(19) United States
(12) Patent Application Publication
(10) Pub. No.: US 2025/0344597 A1
(43) Pub. Date: Nov. 6, 2025

(54) SOLUTION-PROCESSED PEROVSKITE HETEROSTRUCTURES

(71) Applicant: William Marsh Rice University, Houston, TX (US)

(72) Inventors: Aditya D. Mohite, Houston, TX (US); Siraj Sidhik, Houston, TX (US)

(73) Assignee: William Marsh Rice University, Houston, TX (US)

(21) Appl. No.: 18/871,122

(22) PCT Filed: Jun. 5, 2023
(86) PCT No.: PCT/US2023/024466

§ 371 Date: Dec. 2, 2024

Related U.S. Application Data
(60) Provisional application No. 63/365,822, filed on Jun. 3, 2022.

(51) Int. Cl. H10K 71/15; H10K 30/30; H10K 30/40; H10K 71/40; H10K 85/50

(52) U.S. Cl. CPC H10K 71/15; H10K 30/30; H10K 30/40; H10K 71/441; H10K 85/50

(57) ABSTRACT

A solution-processed perovskite heterostructure includes a 3-dimensional (3D) perovskite layer and a 2-dimensional (2D) perovskite layer and a perovskite solar cell including a solution-processed perovskite heterostructure. A method of providing a 2-dimensional (2D) perovskite seed solution includes a 2D perovskite and a polar aprotic solvent, layering the 2D perovskite seed solution onto a 3-dimensional (3D) perovskite layer to form a 3D/2D bilayer and annealing the 3D/2D bilayer such that the aprotic polar solvent evaporates to form a perovskite heterostructure film.

### CROSS-REFERENCE TO RELATED APPLICATIONS

This application claims benefit of U.S. Provisional Patent Application Ser. No. 63/365,822, filed Jun. 3, 2022, which is herein incorporated by reference.

### STATEMENT REGARDING FEDERALLY SPONSORED RESEARCH

This invention was made with government support under Grant No. DE-EE0008843 awarded by the Department of Energy. The government has certain rights in the invention.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method including providing a 2-dimensional (2D) perovskite seed solution comprising a 2D perovskite and a polar aprotic solvent, layering the 2D perovskite seed solution onto a 3-dimensional (3D) perovskite layer to form a 3D/2D bilayer and annealing the 3D/2D bilayer such that the aprotic polar solvent evaporates to form a perovskite heterostructure film.

In another aspect, embodiments disclosed herein relate to a perovskite solar cell including a solution-processed perovskite heterostructure comprising a 3-dimensional (3D) perovskite layer and a 2-dimensional (2D) perovskite layer, wherein the 2D perovskite layer has a phase purity ranging from 90 to 95%.

Other aspects and advantages of the claimed subject matter will be apparent from the following description and the appended claims.

### BRIEF DESCRIPTION OF THE DRAWINGS

FIG. 1A is plot of dielectric constant and Gutmann No. vs processing solvents according to one or more embodiments.

FIG. 1B is a schematic of a method for fabricating mesoscopic 3D/2D heterostructures according to one or more embodiments.

FIG. 2A is a schematic of a phase-selective method for preparing high phase purity films according to one or more embodiments vs. a conventional (“classic”) method for preparing films.

FIG. 2B is an illustration of differently ordered structures obtained in films prepared according to one or more embodiments vs. in films prepared via the conventional (“classic”) method.

FIG. 2C is a plot of the film phase ratio vs. time according to one or more embodiments.

FIG. 2D is a plot of the film phase ratio vs. time according to the conventional film preparation method.

FIG. 3A is a plot of the correlation length for films prepared according to one or more embodiments.

FIG. 3B is a plot of the correlation length derived from the Debye Scherrer equation for films prepared according to one or more embodiments.

FIG. 4A is a schematic of a solar cell device according to one or more embodiments.

FIG. 4B is a plot of current density vs. voltage of films according to one or more embodiments.

FIG. 4C is a plot of current density vs. voltage of solar cell devices according to one or more embodiments.

FIG. 4D are plots of the number of devices vs. the J_{SC}, V_{OC}, fill factor, and peak current efficiency.

FIG. 4E is a plot of the peak current efficiency vs. wavelength for devices prepared according to one or more embodiments and by conventional (“classic”) methods.

FIG. 5 is a plot of the peak current efficiency vs. time at the maximum power point (0.99 V) for a device according to one or more embodiments.

FIG. 6A is a plot of the external quantum efficiency and the integrated current density vs. wavelength for an n=3 device according to one or more embodiments.

FIG. 6B is a plot of the external quantum efficiency and the integrated current density vs. wavelength for an n=4 device according to one or more embodiments.

FIG. 7 is a plot of peak current efficiency vs. time for a device according to one or more embodiments, comparative control devices, and a 3D/2D passivated device.

FIG. 8 is a plot demonstrating the difference in film thickness vs. solution concentration of films prepared according to one or more embodiments.

FIG. 9 is a plot of surface photovoltage vs. 2D layer thickness of films according to one or more embodiments.

### DETAILED DESCRIPTION

Heterostructures are the building blocks for advanced semiconductor devices being developed and produced. Common techniques used for developing these heterostructures include molecular beam epitaxy (MBE), metalorganic chemical vapor deposition (MOCVD), and atomic layer deposition (ALD). However, the use of such techniques in the development of halide perovskite heterostructures is underdeveloped due to the strict temperature and atmospheric control necessary for the growth of such heterostructures. Recently, there have been attempts to create small scale heterostructures with halide perovskites using mechanical exfoliation and transfer methods. However, the use of solution processing techniques for making a perovskite/perovskite heterostructure hasn't been a success due to solvent incompatibility issues.

Embodiments of the present disclosure generally relate to two-dimensional (2D) perovskite heterostructures. 2D perovskite heterostructures described herein may include a 2D perovskite layered onto a suitable substrate. Such 2D perovskite heterostructures may have sharp interfaces and may be used in applications in optoelectronic devices and advanced electronic/spectroscopic studies. Herein, a sharp interface may refer to the transition region from the 2D to the 3D region (or vice versa). Such interfaces may have a size as obtained by forming the transition region by hard fabrication using solution processing.

In one aspect, embodiments disclosed herein relate to a method of preparing solution-process perovskite heterostructures including a substrate layer and a 2D perovskite layer. The 2D perovskite layer may have a crystalline structure and a high phase purity. The method may enable precise control over the phase and composition of the substrate layer and the 2D perovskite layer with arbitrary thickness not achieved previously. In particular embodiments, the substrate is a 3D perovskite. The 3D perovskite may have a general formula of AₓB_{y}X_{z} where A is a small monovalent cation, B is a divalent metal and X is an monovalent anion.

In another aspect, embodiments disclosed herein relate to a perovskite solar cell including a solution-processed perovskite heterostructure. The solution-processed perovskite heterostructures may include a phase-pure 2D perovskite layered onto a 3D perovskite. Herein a “phase-pure 2D perovskite” refers to a 2D perovskite that has at least 90% of a single n-value. Such perovskite heterostructures may exhibit enhanced stability compared to conventional heterostructures known in the art.

In one or more embodiments, a method includes a novel solvent design principle for fabricating a solution-processed heterostructure of a 3D perovskite layer and a 2D perovskite layer, having a high-quality interface and arbitrary film thickness. The disclosed solvent design principle provides control over the n value and phase of the 2D perovskite layer. In contrast to using organic cations for in-situ synthesis of a mixed layered perovskite (mostly n≤2) on top of the 3D layer, the present method uses high-purity 2D perovskite powders to create mesoscopic heterostructures. The present method may leverage two important solvent properties of the processing solvents, the dielectric constant (ε) and the Guttman number (DN), which controls the coordination between the precursor ions and the solvent used.

A method in accordance with the present disclosure includes providing a 2D perovskite seed solution. The seed solution may include a 2D perovskite and a processing solvent. In one or more embodiments, the 2D perovskite layer includes 2D perovskites having a general formula of L′AₓB_{y}X_{z} according to L′Aₙ₋₁BₙX₃ₙ₊₁, where L′ is a long chain organic cation, A is a small monovalent cation, B is a divalent metal, X is a monovalent anion and n is the number of octahedra in the quantum well, which may also be referred to as the layer thickness. In one or more embodiments, n has a value in the range from 1 to 7. In particular embodiments, n is less than or equal to 4. In one or more embodiments, a phase pure film is described by the above general formula for a single n value. Suitable 2D perovskites may be halide perovskites such as Ruddlesden-popper 2D perovskites, Dion-Jacobson 2D perovskites, Alternating Cation 2D perovskites, and combinations thereof, among others. For example, suitable 2D perovskites may include the compounds listed in Table 1.

TABLE 1

| | DJ | | | | |
|---|---|---|---|---|---|
| Space | or | | No. of | Spacer (interlayer) | Intralayer |
| group | RP | Compound | layers | cation | cation |
| Pbca | RP | [CH₃(CH₂)₃NH₃]₂PbI₄ | 1 | Butylammonium | — |
| Pbca | RP | [CH₃(CH₂)₃NH₃]₂SnI₄ | 1 | Butylammonium | — |
| Pnma | else | [CH₃(CH₂)₃NH₃]₂GeI₄ | 1 | Butylammonium | — |
| Pbca | RP | [CH₃(CH₂)₃NH₃]₂PbBr₄ | 1 | Butylammonium | — |
| Cmcm | RP | [CH₃(CH₂)₃NH₃]₂[CH₃NH₃]Pb₂I₇ | 2 | Butylammonium | Methyl- |
| (Cccm) | | | | | ammonium |
| Cmca | RP | [CH₃(CH₂)₃NH₃]₂[CH₃NH₃]₂Pb₃I₁₀ | 3 | Butylammonium | Methyl- |
| (Acam) | | | | | ammonium |
| Cmcm | RP | [CH₃(CH₂)₃NH₃]₂[CH₃NH₃]₃Pb₄I₁₃ | 4 | Butylammonium | Methyl- |
| (Acam) | | | | | ammonium |
| Ama2 | RP | [CH₃(CH₂)₃NH₃]₂[CH₃NH₃]Pb₂I₇ | 2 | Butylammonium | Methyl- |
| | | | | | ammonium |
| Cmca | RP | [CH₃(CH₂)₃NH₃]₂[CH₃NH₃]₄Pb₅I₁₆ | 5 | Butylammonium | Methyl- |
| (Acam) | | | | | ammonium |
| Aba2 | RP | [CH₃(CH₂)₃NH₃]₂[CH₃NH₃]₄Pb₅I₁₆ | 5 | Butylammonium | Methyl- |
| (C2cb) | | | | | ammonium |
| Cmc21 | else | [CH₃CH₂NH₃]₄Pb₃Cl₁₀ | 3 | Ethylammonium | — |
| Aba2(C2cb) | RP | [CH₃CH₂NH₃]₄Pb₃Br₁₀ | 3 | Ethylammonium | — |
| Cmc21 | else | [CH₃CH₂NH₃]₄Pb₃Cl₁₀ | 3 | Ethylammonium | — |
| (A21ma) | | | | | |
| Pbca | else | [CH₃(CH₂)₃NH₃]₂PbI₄ | 1 | Butylammonium | — |
| Pbca | RP | [CH₃(CH₂)₃NH₃]₂PbI₄ | 1 | Butylammonium | — |
| P21/c | else | [CH₃(CH₂)₄NH₃]₂PbI₄ | 1 | Pentylammonium | — |
| (P21/a) | | | | | |
| P21/c | else | [CH₃(CH₂)₄NH₃]₂PbI₄ | 1 | Pentylammonium | — |
| (P21/a) | | | | | |
| Pbca | RP | [CH₃(CH₂)₄NH₃]₂PbI₄ | 1 | Pentylammonium | — |
| P21/c | else | [CH₃(CH₂)₅NH₃]₂PbI₄ | 1 | Hexylammonium | — |
| (P21/a) | | | | | |
| Pbca | RP | [CH₃(CH₂)₅NH₃]₂PbI₄ | 1 | Hexylammonium | — |
| P21/c | else | [CH₃(CH₂)₆NH₃]₂PbI₄ | 1 | Heptylammonium | — |
| (P21/a) | | | | | |
| Pbca | RP | [CH₃(CH₂)₆NH₃]₂PbI₄ | 1 | Heptylammonium | — |
| Pbca | RP | [CH₃(CH₂)₆NH₃]₂PbI₄ | 1 | Heptylammonium | — |
| P21/c | else | [CH₃(CH₂)₇NH₃]₂PbI₄ | 1 | Octylammonium | — |
| (P21/a) | | | | | |
| Pbca | RP | [CH₃(CH₂)₇NH₃]₂PbI₄ | 1 | Octylammonium | — |
| Cmca | RP | [CH₃(CH₂)₈NH₃]₂PbI₄ | 1 | Nonylammonium | — |
| (Acam) | | | | | |
| P21/c | else | [CH₃(CH₂)₈NH₃]₂PbI₄ | 1 | Nonylammonium | — |
| (P21/a) | | | | | |
| Pbca | RP | [CH₃(CH₂)₈NH₃]₂PbI₄ | 1 | Nonylammonium | — |
| P21/c | else | [CH₃(CH₂)₈NH₃]₂PbI₄ | 1 | Decylammonium | — |
| (P21/a) | | | | | |
| Pbca | RP | [CH₃(CH₂)₉NH₃]₂PbI₄ | 1 | Decylammonium | — |
| Pbca | RP | [CH₃(CH₂)₉NH₃]₂PbI₄ | 1 | Decylammonium | — |
| Pbca | RP | [CH₃(CH₂)₉NH₃]₂PbI₄ | 1 | Decylammonium | — |
| Pbca | RP | [CH₃(CH₂)₉NH₃]₂PbI₄ | 1 | Decylammonium | — |
| Pbca | RP | [CH₃(CH₂)₉NH₃]₂PbI₄ | 1 | Decylammonium | — |
| P21/c | else | [NH₃(CH₂)₆NH₃]PbI₄ | 1 | 1,6-hexanediammonium | — |
| P21/c | else | [NH₃(CH₂)₆NH₃]PbBr₄ | 1 | 1,6-hexanediammonium | — |
| P21/c | else | [NH₃(CH₂)₆NH₃]PbI₄ | 1 | 1,6-hexanediammonium | — |
| P21/c | else | [NH₃(CH₂)₈NH₃]PbI₄ | 1 | 1,8-octanediammonium | — |
| P21/c | DJ | [NH₃(CH₂)₁₂NH₃]PbI₄ | 1 | 1,12-dodecanediammonium | — |
| P-1 | else | [NH₃(CH₂)₄NH₃]PbBr₄ | 1 | 1,4-butyldiamine | — |
| C2/c | else | [NH₃(CH₂)₄NH₃]PbI₄ | 1 | 1,4-butyldiamine | — |
| P21/c | else | [NH₃(CH₂)₈NH₃]PbI₄ | 1 | 1,8-octanediammonium | — |
| P21/c | else | [NH₃(CH₂)₁₀NH₃]PbBr₄ | 1 | 1,10-decanediammonium | — |
| P21/c | DJ | [NH₃(CH₂)₁₂NH₃]PbI₄ | 1 | 1,12-dodecanediammonium | — |
| P21/c | DJ | [NH₃C₁₀H₆NH₃]PbI₄ | 1 | Naphthalene-1,5-diamine | — |
| Cc | RP | [NH₃(CH₂)₈NH₃][CH₃NH₃]Pb₂I₇ | 2 | 1,8-octanediammonium | Methyl- |
| | | | | | ammonium |
| Pc | RP | [NH₃(CH₂)₈NH₃][CH₃NH₃]₂Pb₃I₁₀ | 3 | 1,8-octanediammonium | Methyl- |
| | | | | | ammonium |
| Cc | RP | [NH₃(CH₂)₈NH₃][CH₃NH₃]₃Pb₄I₁₄ | 4 | 1,8-octanediammonium | Methyl- |
| | | | | | ammonium |
| Cc | else | [NH₃(CH₂)₉NH₃]PbI₄ | 1 | 1,9-nonanediammonium | — |
| Cc | RP | [NH₃(CH₂)₉NH₃][CH₃NH₃]Pb₂I₇ | 2 | 1,9-nonanediammonium | Methyl- |
| | | | | | ammonium |
| Pc | RP | [NH₃(CH₂)₉NH₃][CH₃NH₃]₂Pb₃I₁₀ | 3 | 1,9-nonanediammonium | Methyl- |
| | | | | | ammonium |
| Pbca | RP | [CH₃(CH₂)₃NH₃]₂PbBr₄ | 1 | Butylammonium | — |
| Pbca | RP | [CH₃(CH₂)₃NH₃]₂SnI₄ | 1 | Butylammonium | — |
| P21/c | else | [NH₃(CH₂)₃NH₂CH₃]PbBr₄ | 1 | N1-methylpropane-1,3- | — |
| | | | | diammonium | |
| Imma | else | [C(NH₂)₃][CH₃NH₃]₃Pb₃I₁₀ | 3 | Guanidinium | Methyl- |
| | | | | | ammonium |
| Amma | else | [C(NH₂)₃][CH₃NH₃]₂Pb₂I₇ | 2 | Guanidinium | Methyl- |
| | | | | | ammonium |
| Imma | else | [C(NH₂)₃][CH₃NH₃]PbI₄ | 1 | Guanidinium, | — |
| | | | | Methylammonium | |
| C2 | else | [NH₃(CH₂)₂O(CH₂)₂O(CH₂)₂NH₃]PbCl₄ | 1 | 1,8-Diamino-3,6-dioxaoctane | — |
| P21/c | else | [NH₃(CH₂)₂O(CH₂)₂O(CH₂)₂NH₃]PbBr₄ | 1 | 1,8-Diamino-3,6-dioxaoctane | — |
| P21/c | else | [NH₃(CH₂)₂O(CH₂)₂O(CH₂)₂NH₃]PbI₄ | 1 | 1,8-Diamino-3,6-dioxaoctane | — |
| P21/c | DJ | [NH₃(CH₂)₂SC(NH₂)NH₃]PbBr₄ | 1 | 2-(aminoethyl)- | — |
| | | | | isothiourea protonated | |
| P21/c | else | [CHC(CH₂)₂NH₃]₂PbBr₄ | 1 | 4-amino-1-butyne protonated | — |
| P-1 | else | [ICHC(I)(CH₂)₂NH₃]₂PbBr₄ | 1 | 4-amino-1,2-diiodo-1- | — |
| | | | | butene protonated | |
| P21/c | else | [CH₂CH(CH₂)₂NH₃]₂PbBr₄ | 1 | 4-aminobutylene protonated | — |
| Pnma | else | [F(CH₂)₂NH₃]₂PbCl₄ | 1 | 2-fluoroethylammonium | — |
| P21/c | — | [(CH₃)₂CHCH₂NH₃]₂[PbBr₄] | 1 | Isobutylammonium | — |
| Cmca | RP | [(CH₃)₂CHCH₂NH₃]₂[PbBr₄] | 1 | Isobutylammonium | — |
| P21/c | else | [HO(CH₂)₂NH₃]₂PbI₄ | 1 | Ethanolammonium | — |
| P21/c | else | [HO(CH₂)₃NH₃]₂PbI₄ | 1 | 3-aminopropanol | — |
| | | | | protonated | |
| P21/c | else | [I(CH₂)₂NH₃]₂PbI₄ | 1 | 2-iodoethylammonium | — |
| P21/c | else | [I(CH₂)₃NH₃]₂PbI₄ | 1 | 3-iodopropylammonium | — |
| P21/c | else | [I(CH₂)₄NH₃]₂PbI₄ | 1 | 4-iodobutylammonium | — |
| P21/c | DJ | [I(CH₂)₅NH₃]₂PbI₄ | 1 | 5-iodopentylammonium | — |
| Pbca | RP | [I(CH₂)₆NH₃]₂PbI₄ | 1 | 6-iodohexylammonium | — |
| Pnma | else | [Br(CH₂)₂NH₃]₂PbI₄ | 1 | 2-bromoethylammonium | — |
| P21/c | else | [NH₃(CH₂)₂SS(CH₂)₂NH₃]₂Pb₂I₈ | 1 | 2,2′-dithiobisethan- | — |
| | | | | ammonium | |
| P21/c | RP | [C₃H₅NH₃]₂PbI₄ | 1 | Cyclopropylammonium | — |
| P21/c | else | [C₃H₅NH₃]₂PbBr₄ | 1 | Cyclopropylammonium | — |
| P21/c | else | [C₄H₇NH₃]₂PbBr₄ | 1 | Cyclobutylammonium | — |
| P21/c | else | [C₅H₉NH₃]₂PbBr₄ | 1 | Cyclopentylammonium | — |
| Cmc21 | else | [C₆H₁₁NH₃]₂PbBr₄ | 1 | Cyclohexylammonium | — |
| P21/c | else | [C₃H₅NH₃]₂PbCl₄ | 1 | Cyclopropylammonium | — |
| P21/c | else | [C₄H₇NH₃]₂PbCl₄ | 1 | Cyclobutylammonium | — |
| Cmca | else | [C₅H₉NH₃]₂PbCl₄ | 1 | Cyclopentylammonium | — |
| P21/m | else | [C₆H₁₁NH₃]₄Pb₂Cl₈ | 1 | Cyclohexylammonium | — |
| P21/c | else | [C₆H₁₀CH₂NH₃]₂PbBr₄ | 1 | Cyclohexylmethylammonium | — |
| P21/c | else | [NH₂(C₂H₄)₂NH₂]PbCl₄ | 1 | Piperazinium | — |
| P21/c | else | [C₅H₁INCH₂NH₃]PbI₄ | 1 | 3-(aminomethyl)-piperidinium | — |
| Cc | DJ | [C₅H₁₁NCH₂NH₃ ][CH₃NH₃]Pb₂I₇ | 2 | 3-(aminomethyl)-piperidinium | Methyl- |
| | | | | | ammonium |
| Pc | DJ | [C₅H₁₁NCH₂NH₃ ][CH₃NH₃]Pb₂I₁₀ | 3 | 3-(aminomethyl)-piperidinium | Methyl- |
| | | | | | ammonium |
| Cc | DJ | [C₅H₁₁NCH₂NH₃ ][CH₃NH₃]₃Pb₄I₁₃ | 4 | 3-(aminomethyl)-piperidinium | Methyl- |
| | | | | | ammonium |
| Pc | DJ | [C₅H₁₁NCH₂NH₃]PbI₄ | 1 | 4-(aminomethyl)-piperidinium | — |
| Cc | DJ | [C₅H₁₁NCH₂NH₃][CH₃NH₃]Pb₂I₇ | 2 | 4-(aminomethyl)-piperidinium | Methyl- |
| | | | | | ammonium |
| P1 | DJ | [C₅H₁₁NCH₂NH₃][CH₃NH₃]₂Pb₃I₁₀ | 3 | 4-(aminomethyl)-piperidinium | Methyl- |
| | | | | | ammonium |
| Cc | DJ | [C₅H₁₁NCH₂NH₃][CH₃NH₃]₃Pb₄I₁₃ | 4 | 4-(aminomethyl)-piperidinium | Methyl- |
| | | | | | ammonium |
| Pbca | RP | [(C₆H₁₁)PH₃]₂SnI₄ | 1 | Cyclohexylphosphonium | — |
| P21/c | else | [NH₃CH₂C₆H₁₀CH₂NH₃]PbI₄ | 1 | 4,4′-bipyridine | — |
| Cmc21 | else | [C₆H₅CH₂NH₃]PbCl₄ | 1 | Phenylmethylammonium | — |
| Cmc21 | else | [C₆H₅CH₂NH₃]PbCl₄ | 1 | Phenylmethylammonium | — |
| Cmc21 | else | [C₆H₅CH₂NH₃]PbCl₄ | 1 | Phenylmethylammonium | — |
| Cmc21 | else | [C₆H₅CH₂NH₃]PbCl₄ | 1 | Phenylmethylammonium | — |
| Cmc21 | else | [C₆H₅CH₂NH₃]PbCl₄ | 1 | Phenylmethylammonium | — |
| Cmca | RP | [C₆H₅CH₂NH₃]PbCl₄ | 1 | Phenylmethylammonium | — |
| Cmc21 | else | [C₆H₅CH₂NH₃]PbCl₄ | 1 | Phenylmethylammonium | — |
| Cmca | RP | [C₆H₅CH₂NH₃]PbBr₄ | 1 | Phenylmethylammonium | — |
| Cmca | RP | [C₆H₅CH₂NH₃]PbBr₄ | 1 | Phenylmethylammonium | — |
| Cmca | RP | [C₆H₅CH₂NH₃]PbBr₄ | 1 | Phenylmethylammonium | — |
| Cmca | RP | [C₆H₅CH₂NH₃]PbBr₄ | 1 | Phenylmethylammonium | — |
| Cmc21 | else | [C₆H₅CH₂NH₃]₂PbCl₄ | 1 | Phenylmethylammonium | — |
| Pbca | else | [C₆H₅CH₂NH₃]₂PbI₄ | 1 | Phenylmethylammonium | — |
| Cc | else | [C₄H₃S(CH₂)₂NH₃]₂PbI₄ | 1 | 2-(2-thienyl)-ethanaminium | — |
| P21/c | else | [C₃H₄N₂(CH₂)₂NH₃]PbI₄ | 1 | Histammonium | — |
| P21/c | else | [C₃H₄N₂(CH₂)₂NH₃]SnI₄ | 1 | Histammonium | — |
| Pbca | else | [C₆H₅CH₂NH₃]₂PbI₄ | 1 | Phenylmethylammonium | — |
| Pbca | RP | [C₆H₅CH₂NH₃]₂SnI₄ | 1 | Phenylmethylammonium | — |
| Aba2 | RP | [C₄H₃SCH₂NH₃]₂[CH₃NH₃]Pb₂I₇ | 2 | 2-(2-thienyl)-methylaminium | Methyl- |
| | | | | | ammonium |
| Pbca | RP | [C₄H₃SCH₂NH₃]₂PbI₄ | 1 | 2-(2-thienyl)-methylaminium | — |
| Pbca | else | [C₅H₁₁NCH₂NH₃]PbBr₄ | 1 | 2-(aminomethyl)-piperidinium | — |
| P21/c | else | [BrC₆H₄(CH₂)₂NH₃]₂SnI₄ | 1 | 2-bromophenylethyl-ammonium | — |
| P21/c | else | [(CH₃)₂NHC₆H₄NH₃]PbCl₄ | 1 | N,N-Dimethylbenzene- | — |
| | | | | 1,4-diammonium | |
| P2/c | else | [NH₃C₆H₄NH₃]PbCl₄ | 1 | m-phenylenediammonium | — |
| P21/c | else | [(CH₃)₂NHC₆H₄NH₃]PbBr₄ | 1 | N,N-Dimethylbenzene- | — |
| | | | | 1,4-diammonium | |
| C2/c | else | [NH₂C(NH₂)C₅H₄NH]PbBr₄ | 1 | 3-amidinopyridinium | — |
| Cmc21 | RP | [C₆H₅CH₂NH₃]₂PbBr₄ | 1 | Phenylmethylammonium | — |
| P-1 | else | [C₆H₅(CH₂)₂NH₃]₂PbI₄ | 1 | Phenylethylammonium | — |
| Cmc21 | else | [C₁₀H₇CH₂NH₃]₂PbBr₄ | 1 | 1-(2-naphthyl)-methanammonium | — |
| Pc | else | [C₁₀H₇(CH₂)₂NH₃]₂PbI₄₄ | 1 | 2-(2-naphthyl)-ethanammonium | — |
| P1 | else | [C₁₀H₇(CH₂)₂NH₃]₂PbBr₄ | 1 | 2-(2-naphthyl)-ethanammonium | — |
| C2/c | else | [C₇H₇N₂]₂PbI₄ | 1 | Benzimidazolium | — |
| C2/c | else | [C₇H₇N₂]₂PbCl₄ | 1 | Benzimidazolium | — |
| C2/c | else | [C₇H₇N₂]₂PbBr₄ | 1 | Benzimidazolium | — |
| Cc | else | [C₁₀H₇₀O(CH₂)₂NH₃]₂PbI₄ | 1 | Naphthalene-O-ethylammonium | — |
| P21/c | else | [C₁₀H₇₀O(CH₂)₃NH₃]₂PbI₄ | 1 | Naphthalene-O-propylammonium | — |
| P-1 | else | [C₁₀H₇₀O(CH₂)₃NH₃]₂PbI₄*0.5(C₄H₆O₂) | 1 | Naphthalene-O-ethylammonium | — |
| Cc | else | [C₁₆H₉O(CH₂)₂NH₃]₂PbI₄ | 1 | Pyrene-O-ethylammonium | — |
| Cc | else | [C₁₆H₉O(CH₂)₃NH₃]₂PbI₄ | 1 | Pyrene-O-propylammonium | — |
| C2/c | else | [C₁₆H₉O(CH₂)₄NH₃]₂PbI₄ | 1 | Pyrene-O-butylammonium | — |
| P21/c | else | [C₂₀H₁₁O(CH₂)₂NH₃]₂PbI₄ | 1 | Perylene-O-ethylammonium | — |
| P-1 | else | [NH₃(CH₂)₂S(C₄H₃S)₂S(CH₂)₂NH₃]PbI₄ | 1 | 5-ammonium-ethylsulfanyl- | — |
| | | | | 2,2′-bithiophene | |
| P21/c | else | [FC₆H₅CH₂NH₃]₂PbI₄ | 1 | 4-fluorophenyl-methylammonium | — |
| P21/c | else | [C₃H₃N₂(CH₂)₃NH₃]PbBr₄ | 1 | N-(3-aminopropyl)-imidazole | — |
| C2/c | else | [C₇H₇N₂]₂SnI₄ | 1 | Benzimidazolium | — |
| P21 | else | [ClC₆H₅CH₂NH₃]₂PbI₄ | 1 | 4-chlorophenylmethyl- | — |
| | | | | ammonium | |
| P-1 | else | [C₆H₅(CH₂)₂NH₃]₂PbBr₄ | 1 | Phenylethylammonium | — |
| Pc | DJ | [C₅H₁₁NCH₂NH₃][CH₃NH₃]₆Pb₇I₂₂ | 7 | 4-(aminomethyl)-piperidinium | Methyl- |
| | | | | | ammonium |
| Ama2 | RP | [CH₃(CH₂)₃NH₃]₂[CH₃NH₃]₅Pb₆I₁₉ | 6 | Butylammonium | Methyl- |
| | | | | | ammonium |
| Aba2 | RP | [CH₃(CH₂)₃NH₃]₂[CH₃NH₃]₆Pb₇I₂₂ | 7 | Butylammonium | Methyl- |
| | | | | | ammonium |
| P-1 | else | [FC₆H₄(CH₂)₂NH₃]₂PbI₄ | 1 | 2-fluorophenylethyl- | — |
| | | | | ammonium | |
| C2/c | else | [FC₆H₄(CH₂)₂NH₃]₂PbI₄ | 1 | 3-fluorophenylethyl- | — |
| | | | | ammonium | |
| C2/c | else | [FC₆H₄(CH₂)₂NH₃]₂[CH₃NH₃]Pb₂I₇ | 2 | 4-fluorophenylethyl- | Methyl- |
| | | | | ammonium | ammonium |
| P21 | else | [BrC₆H₅CH₂NH₃]₂PbI₄ | 1 | 4-bromophenylmethyl- | — |
| | | | | ammonium | |
| P21/c | else | [IC₆H₅CH₂NH₃]₂PbI₄ | 1 | 4-iodophenylmethyl- | — |
| | | | | ammonium | |
| Cmmm | — | Cs[C(NH₂)₃]Pb₂Br₇ | 2 | Guanidinium, Caesium | — |
| Imma | — | Cs[C(NH₂)₃]PbBr₄ | 1 | Guanidinium, Caesium | — |
| Pnnm | — | Cs[C(NH₂)₃]PbI₄ | 1 | Guanidinium, Caesium | — |
| Pnnm | — | Cs[C(NH₂)₃]PbI₄ | 1 | Guanidinium, Caesium | — |
| P21/c | else | [FC₆H₄(CH₂)₂NH₃]₂PbI₄ | 1 | 4-fluorophenylethyl- | — |
| | | | | ammonium | |
| P1 | else | [FC₆H₄(CH₂)₂NH₃]₂PbI₄ | 1 | 2-fluorophenylethyl- | — |
| | | | | ammonium | |
| P1 | else | [FC₆H₄(CH₂)₂NH₃]₂PbI₄ | 1 | 3-fluorophenylethyl- | — |
| | | | | ammonium | |
| P21/c | else | [FC₆H₄(CH₂)₂NH₃]₂ | 3 | 4-fluorophenylethyl- | Methyl- |
| | | [CH₃NH₃]₂Pb₃I₁₀ | | ammonium | ammonium |
| P21/c | else | [FC₆H₄(CH₂)₂NH₃]₂[CH₃NH₃₂]₂Pb₃I₁₀ | 3 | 4-fluorophenylethyl- | Methyl- |
| | | | | ammonium | ammonium |
| P21/c | else | [FC₆H₄(CH₂)₂NH₃]₂PbI₄ | 1 | 4-fluorophenylethyl- | — |
| | | | | ammonium | |
| Pmna | DJ | [C(NH₂)₃]₂SnI₄ | 1 | Guanidinium | — |
| Pnnm | DJ | [C(NH₂)₃]₂SnI₄ | 1 | Guanidinium | — |
| P21/c | else | [C(NH₂)₃]₂SnI₄ | 1 | Guanidinium | — |
| P-1 | else | [C(NH₂)₃]₂SnI₄ | 1 | Guanidinium | — |
| Pmna | DJ | [C(NH₂)₃]₂PbI₄ | 1 | Guanidinium | — |
| Pnnm | DJ | [C(NH₂)₃]₂PbI₄ | 1 | Guanidinium | — |
| P21/c | else | [C(NH₂)₃]₂PbI₄ | 1 | Guanidinium | — |
| P-1 | else | [C₃H₅N₂][C(NH₂)₃]PbBr₄ | 1 | Imidazolium, Guanidinium | — |
| P21/c | else | [C₂H₄N₃][C(NH₂)₃]PbBr₄ | 1 | 1,2,4-triazolium, | — |
| | | | | Guanidinium | |
| P2/c | — | [C₂H₄N₃][C(NH₂)₃]PbBr₄ | 1 | 1,2,4-triazolium, | — |
| | | | | Guanidinium | |
| P-1 | else | [C₃H₅N₂][C(NH₂)₃]PbBr₄ | 1 | Imidazolium, Guanidinium | — |
| Cmcm | RP | [CH₃(CH₂)₄NH₃]₂[CH₃NH₃]Pb₂I₇ | 2 | Pentylammonium | Methyl- |
| | | | | | ammonium |
| C2/c | else | [CH₃(CH₂)₄NH₃]₂[CH₃NH₃]Pb₂I₇ | 2 | Pentylammonium | Methyl- |
| | | | | | ammonium |
| Cmcm | RP | [CH₃(CH₂)₃NH₃]₂[CH₃NH₃]Pb₂I₇ | 2 | Butylammonium | Methyl- |
| | | | | | ammonium |
| P-1 | else | [CH₃(CH₂)₃NH₃]₂[CH₃NH₃]Pb₂I₇ | 2 | Butylammonium | Methyl- |
| | | | | | ammonium |
| P21/m | else | [CH₃(CH₂)₄NH₃]₂[CH₃NH₃]Pb₂I₇ | 2 | Pentylammonium | Methyl- |
| | | | | | ammonium |
| Cmca | RP | [CH₃(CH₂)₃NH₃]₂[CH₃NH₃]₂Pb₃I₁₀ | 3 | Butylammonium | Methyl- |
| | | | | | ammonium |
| P-1 | else | [CH₃(CH₂)₃NH₃]₂[CH₃NH₃]₂Pb₄I₁₀ | 3 | Butylammonium | Methyl- |
| | | | | | ammonium |
| Cmcm | RP | [CH₃(CH₂)₃NH₃]₂[CH₃NH₃]₃Pb₄I₁₃ | 4 | Butylammonium | Methyl- |
| | | | | | ammonium |
| P-1 | else | [CH₃(CH₂)₃NH₃]₂[CH₃NH₃]₃Pb₄I₁₃ | 4 | Butylammonium | Methyl- |
| | | | | | ammonium |
| Cmcm | RP | [CH₃(CH₂)₅NH₃]₂[CH₃NH₃]Pb₂I₇ | 2 | Hexylammonium | Methyl- |
| | | | | | ammonium |
| C2/c | else | [CH₃(CH₂)₅NH₃]₂[CH₃NH₃]Pb₂I₇ | 2 | Hexylammonium | Methyl- |
| | | | | | ammonium |
| Cmcm | RP | [CH₃(CH₂)₃NH₃]₂[HC(NH₂)₂]Pb₂I₇ | 2 | Butylammonium | Form- |
| | | | | | amidinium |
| P-1 | else | [CH₃(CH₂)₃NH₃]₂[HC(NH₂)₂]Pb₂I₇ | 2 | Butylammonium | Form- |
| | | | | | amidinium |
| P-1 | else | [CH₃NHNH₃]₂PbI₄ | 1 | Methylhydrazinium | — |
| Pccn | else | [CH₃NHNH₃]₂PbI₄ | 1 | Methylhydrazinium | — |
| Pmmn | else | [CH₃NHNH₃]₂PbI₄ | 1 | Methylhydrazinium | — |
| Pmmn | else | [CH₃NHNH₃]₂PbI₄ | 1 | Methylhydrazinium | — |
| P21/c | else | [CH₃(CH₂)₃CH(C₂H₅)CH₂NH₃]₂PbI₄ | 1 | 2-ethyl-hexylammonium | — |
| P21/c | else | [CH₃(CH₂)₄CH(CH₃)NH₃]₂PbI₄ | 1 | 1-methyl-hexylammonium | — |
| P21/c | else | [(C₅H₈)NH₃]PbI₄ | 1 | 1-methyl-butylammonium | — |
| P42/ncm | RP | [CH₃CH₂CH(CH₃)NH₃]₂PbI₄ | 1 | 1-methyl-propylammonium | — |
| P21 | else | [ClC₆H₅CH₂NH₃]₂PbI₄ | 1 | 4-chlorophenylmethyl- | — |
| | | | | ammonium | |
| Cmc21 | else | [C₆H₁₁NH₃]PbBr₄ | 1 | Cyclohexylammonium | — |
| Cmca | RP | [HOOCC₆H₁₀CH₂NH₃]SnI₄ | 1 | | |
| P21/c | else | [I(CH₂)₃NH₃]₂SnI₄ | 1 | 3-iodopropylammonium | — |
| (P21/a) | | | | | |
| Pbca | RP | [HOOC(CH₂)₃NH₃]₂SnI₄ | 1 | γ-Aminobutyric acid | — |
| | | | | protonated | |
| P21/c | else | [C₅H₁₁N(CH₂)₂NH₃]SnI₄ | 1 | 1-(aminoethyl)-piperidinium | — |
| Pnma | DJ | [IC₅H₅N]₂SnI₄ | 1 | 3-iodopyridine | — |
| C2/c | else | [NH₃(CH₂)₅NH₃]SnI₄ | 1 | 1,5-pentyldiammonium | — |
| C2/m | else | [C₆H₅(CH₂)₂NH₃]₂SnI₄ | 1 | Phenylethylammonium | — |
| C2/m | else | [ClC₆H₄(CH₂)₂NH₃]₂SnI₄ | 1 | 2-chlorophenylethyl- | — |
| | | | | ammonium | |
| P-1 | DJ | [F₂C₇H₇N₂]₂SnI₄ | 1 | 5,6-difluorobenzimidazolium | — |
| Pbca | RP | [CH₃(CH₂)₁₁NH₃]₂PbI₄ | 1 | n-dodecylammonium | — |
| P1 | else | [(₂,₃-C₄H₄S(CH₃)-₂,₅- | 1 | 2-(3″′,4′-dimethyl- | — |
| | | C₄H₄S)₂(CH₂)₂NH₃]₂SnI₄ | | [2,2′:5′,2″:5″,2″′- | |
| | | | | quaterthiophen]-5- | |
| | | | | yl)ethan-1-ammonium | |
| P-1 | else | [C₆H₅(CH₂)₂NH₃]₂SnI₄ | 1 | Phenylethylammonium | — |
| Cmca | DJ | [(CH₃)₃N(CH₂)₂NH₃]SnI₄ | 1 | 2-trimethylammonium- | — |
| | | | | ethylammonium | |
| C2/c | else | [(C₃H₆N₂)₂]PbI₄ | 1 | 2,2′-biimidazolium | — |
| C2/c | else | [(C₃H₆N₂)₂]SnI₄ | 1 | 2,2′-biimidazolium | — |
| Pbca | else | [CH₃(CH₂)₃NH₃]₂SnI₄ | 1 | Butylammonium | — |
| C2/c | else | [C₆F₅(CH₂)₂NH₃][C₁₀H₇(CH₂)₂NH₃]SnI₄ | 1 | 2,3,4,5,6-pentafluoro- | — |
| | | | | phenethylammonium, | |
| | | | | 2-naphthyleneethyl- | |
| | | | | ammonium | |
| C2/c | else | [FC₆H₄(CH₂)₂NH₃]₂SnI₄ | 1 | 2-fluorophenylethyl- | — |
| | | | | ammonium | |
| C2/c | else | [FC₆H₄(CH₂)₂NH₃]₂SnI₄ | 1 | 3-fluorophenylethyl- | — |
| | | | | ammonium | |
| P21c | else | [FC₆H₄(CH₂)₂NH₃]₂SnI₄ | 1 | 4-fluorophenylethyl-- | — |
| | | | | ammonium | |
| Cmca | RP | [CH₃(CH₂)₃NH₃]₂[CH₃NH₃]₂Sn₃I₁₀ | 3 | Butylammonium | Methyl- |
| | | | | | ammonium |
| P42 c m | RP | [(CH₃)₂CHNH₃]₃Sn₂I₇ | 2 | isopropylammonium | — |
| Ama2 | RP | (CH₃(CH₂)₃NH₃)₂(CH₃NH₃)Sn₂I₇ | 2 | Butylammonium, | — |
| | | | | Methylammonium | |
| P-1 | else | [C₆H₅(CH₂)₂NH₃]₂GeI₄ | 1 | Phenylethylammonium | — |
| Pbca | else | [CH₃(CH₂)₃NH₃]₂SnI₄ | 1 | Butylammonium | — |
| P21/c | else | [HO(CH₂)₂NH₃]₂SnI₄ | 1 | 2-hydroxyethyl- | — |
| | | | | ammonium | |
| Pmna | else | [HO(CH₂)₂NH₃]₂SnI₄ | 1 | 2-hydroxyethyl- | — |
| | | | | ammonium | |
| P21/c | else | [HO(CH₂)₂NH₃]₂PbI₄ | 1 | 2-hydroxyethyl- | — |
| | | | | ammonium | |
| Pbcn | else | [HO(CH₂)₂NH₃]₂PbBr₄ | 1 | 2-hydroxyethyl- | — |
| | | | | ammonium | |
| Imma | — | Cs[C(NH₂)₃]SnBr₄ | 1 | Caesium, Guanidinium | — |
| Cmmm | — | Cs₂[C(NH₂)₃]Sn₂Br₇ | 2 | Caesium, Guanidinium | Cs |
| C2/m | else | [C₈H₈N₄]SnI₄ | 1 | Benzodiimidazolium | — |
| C2/m | else | [C₈H₈N₄]PbI₄ | 1 | Benzodiimidazolium | — |
| Cmc21 | RP | [CH₃(CH₂)₃NH₃]₂[CH₃NH₃]₂Sn₃Br₁₀ | 3 | Butylammonium | Methyl- |
| | | | | | ammonium |
| Cmca | RP | [CH₃(CH₂)₃NH₃]₂[CH₃NH₃]₂Sn₃Br₁₀ | 3 | Butylammonium | Methyl- |
| | | | | | ammonium |
| I4/m | RP | [CH₃(CH₂)₃NH₃]₂[CH₃NH₃]₂Sn₃Br₁₀ | 3 | Butylammonium | Methyl- |
| | | | | | ammonium |
| Cmc21 | else | [CH₃(CH₂)₃NH₃]₂[CH₃NH₃]₂Sn₃Br₁₀ | 3 | Butylammonium | Methyl- |
| | | | | | ammonium |
| Cmca | RP | [CH₃(CH₂)₃NH₃]₂[CH₃NH₃]₂Sn₃Br₁₀ | 3 | Butylammonium | Methyl- |
| | | | | | ammonium |
| C/2c | else | [C₆H₅(CH₂)₂NH₃]₂SnI₄*C₆H₆ | 1 | Phenylethylammonium | — |
| C/2c | else | [C₆H₅(CH₂)₂NH₃]₂SnI₄*C₆F₆ | 1 | Phenylethylammonium | — |
| C2/m | else | [NH₃(CH₂)₂(C₄H₄S)₄(CH₂)₂NH₃]Bi_{2/3}I₄ | 1 | 5,5″′-bis-(aminoethyl)- | — |
| | | | | 2,2′:5′,2″:5″,2″′- | |
| | | | | quaterthiophene | |
| C2/c | else | [NH₃(CH₂)₂(C₄H₄S)₄(CH₂)₂NH₃]Bi_{2/3}I₄ | 1 | 5,5″′-bis-(aminoethyl)- | — |
| | | | | 2,2′:5′,2″:5″,2″′- | |
| | | | | quaterthiophene | |
| Cmc21 | RP | [C₆H₅CH₂NH₃]₂SnCl₄ | 1 | Phenylmethylammonium | — |
| Cmc21 | RP | [C₆H₅CH₂NH₃]₂SnBr₄ | 1 | Phenylmethylammonium | — |
| Pbca | RP | [C₆H₅CH₂NH₃]₂SnI₄ | 1 | Phenylmethylammonium | — |
| P21/c | else | [C₆H₁₁CH₃NH₃]₂SnI₄ | 1 | Cyclohexylmethylammonium | — |
| Cmca | RP | [C₆H₁₁CH₃NH₃]₂SnI₄ | 1 | Cyclohexylmethylammonium | — |
| P1 | else | [C₆H₅(CH₂)₂NH₃]₂ | 3 | Phenylethylammonium | — |
| | | [CH₃NH₃]₂Pb₃I₁₀ | | | |
| P21/c | else | [C₃H₄N₂(CH₂)₂NH₃]PbI₄ | 1 | Histammonium | — |
| Pbca | else | [C₆H₅CH₂NH₃]PbI₄ | 1 | Phenylmethylammonium | — |
| P21/c | else | [I(CH₂)₂NH₃]₂PbI₄ | 1 | 2-iodoethylammonium | — |
| (P21/a) | | | | | |
| C2/c | else | [Br(CH₂)₂NH₃]₂PbI₄ | 1 | 2-bromoethylammonium | — |
| Pnma | else | [Br(CH₂)₂NH₃]₂PbI₄ | 1 | 2-bromoethylammonium | — |
| (Pbnm) | | | | | |
| P21/c | else | [NH₃(CH₂)₂SS(CH₂)₂NH₃]₂PbI₄ | 1 | 2,2′-dithiobisethan- | — |
| (P21/a) | | | | ammonium | |
| P21/c | else | [NH₃(CH₂)₂SS(CH₂)₂NH₃]₂PbI₄ | 1 | 2,2′-dithiobisethan- | — |
| (P21/n) | | | | ammonium | |
| Pna21 | else | [NH₃(CH₂)₂SS(CH₂)₂NH₃]₂Snl₄ | 1 | 2,2′-dithiobisethan- | — |
| (P21cn) | | | | ammonium | |
| Pbca | else | [C₅H₄N(CH₂)NH₃]PbI₄ | 1 | 3-Pyridinylmethylammonium | — |
| Pbca | else | [C₅H₄N(CH₂)NH₃]PbI₄ | 1 | 3-Pyridinylmethylammonium | — |
| Pbca | else | [C₅H₄N(CH₂)NH₃]PbBr₄ | 1 | 3-Pyridinylmethylammonium | — |
| Pbca | else | [CH₄N(CH₂)NH₃]PbBr₄ | 1 | 3-Pyridinylmethylammonium | — |
| Pna21 | else | [C₅H₄N(CH₂)NH₃]Pb₄Cl₁₆ | 1 | 3-Pyridinylmethylammonium | — |
| Pbca | else | [C₅H₄N(CH₂)NH₃]PbCl₄ | 1 | 3-Pyridinylmethylammonium | — |
| P21/c | else | [(CH₃)₂NH(CH₂)₂NH₃]PbBr₄ | 1 | 2-(dimethylamino)ethyl- | — |
| | | | | ammonium | |
| P21/c | else | [(CH₃)₂NH(CH₂)₃NH₃]PbBr₄ | 1 | N,N′-dimethylpropane- | — |
| | | | | 1,3-diammonium | |
| Aba2 | else | [(CH₃)₂NH(CH₂)₄NH₃]PbBr₄ | 1 | 2-(dimethylamino)butyl- | — |
| | | | | ammonium | |
| P1 | else | [(HOOC)₂C₇H₇N₂]₂SnI₄ | 1 | 5,6-dicarboxybenzimidazolium | — |
| P21/c | else | [(CH₃)₂NHC₆H₄NH₃]PbI₄ | 1 | N,N-Dimethylbenzene- | — |
| (21/n) | | | | 1,4-diammonium | |
| C2/m | else | [FC₆H₅(CH)₂C₆H₅(CH₂)₂NH₃]₂[CH₃NH₃]Sn₂I₇ | 2 | 2-(4-(3-fluoro)stil- | — |
| | | | | benyl)ethanammonium | |
| P-1 | else | [FC₆H₅(CH)₂C₆H₅(CH₂)₂NH₃]₂[CH₃NH₃]Sn₂I₇ | 1 | 2-(4-(3-fluoro)stil- | Methyl- |
| | | | | benyl)ethanammonium | ammonium |
| C2/m | else | [C₆H₅(CH₂)₂NH₃]SnI₄ | 1 | Phenylethylammonium | — |
| P-1 | else | [FC₆H₅(CH)₂C₆H₅(CH₂)₂NH₃]₂SnI₄ | 1 | 2-(4-(3-fluoro)stil- | — |
| | | | | benyl)ethanammonium | |
| C2/m | else | [FC₆H₅(CH)₂C₆H₅(CH₂)₂NH₃]₂SnI₄ | 1 | 2-(4-(3-fluoro)stil- | — |
| | | | | benyl)ethanammonium | |
| P21/c | else | [NH₃(CH₂)₈NH₃]PbBr₄ | 1 | 1,8-octanediammonium | — |
| P-1 | else | [NH₃(CH₂)₄NH₃]PbBr₄ | 1 | 1,4-butanediammonium | — |
| P21/c | else | [COOH(CH₂)₃NH₃]₂PbBr₄ | 1 | 3-carboxypropan-1- | — |
| | | | | ammonium (γ- | |
| | | | | ammoniobutyric acid) | |
| P21/c | else | [C₃H₄N₂(CH₂)₂NH₃]PbBr₄ | 1 | Histammonium | — |
| P21/c | else | [NH₃C₆H₄(CH₂)₂NH₃]PbBr₄ | 1 | 3-(2-aminoethyl)anilinium | — |
| Pbca | else | [HO(CH₂)₂NH₃]₂PbBr₄ | 1 | 2-hydroxyethylammonium | — |
| P21/c | else | [C₃H₄N₂(CH₂)₂NH₃]PbBr₄ | 1 | Histammonium | — |
| C2/c | else | [NH₃CH₂CH(CH₃)(CH₂)₃NH₃]PbBr₄ | 1 | | — |
| P-1 | else | [C₆H₅(CH₂)₂NH₃]₂SnBr₄ | 1 | Phenylethylammonium | — |
| P-1 | else | [C₆H₉(CH₂)₂NH₃]₂SnBr₄ | 1 | 2-(1-cyclohexenyl)ethyl- | — |
| | | | | ammonium | |
| P-1 | else | [C₆H₉(CH₂)₂NH₃]₂PbBr₄ | 1 | 2-(1-cyclohexenyl)ethyl- | — |
| | | | | ammonium | |
| P-1 | else | [C₆H₅(CH₂)₂NH₃]₂PbI₄ | 1 | Phenylethylammonium | — |
| P-1 | else | [C₆H₅(CH₂)₂NH₃]₂PbBr₄ | 1 | Phenylethylammonium | — |
| Cc | else | [NH₃(CH₂)₂(CH₃)(CH₂)₃NH₃]PbCl₄ | 1 | | — |
| Pnma | else | [F(CH₂)₂NH₃]₂PbBr₄ | 1 | 2-fluoroethylammonium | — |
| Pbca | RP | [F₂CHCH₂NH₃]₂PbBr₄ | 1 | 2,2-difluoroethylammonium | — |
| Pnma | else | [F₃CCH₂NH₃]₂PbBr₄ | 1 | 2,2,2-trifluoroethylammonium | — |
| Pca21 | else | [NH₂C₅H₉CH₂NH₃]PbBr₄ | 1 | 4-(aminomethyl)piperidinium | — |
| C2/c | DJ | [CH₃NHC₄H₈NH₂]₂Pb₃Br₁₀ | 3 | 1-methylpiperazine | — |
| P21/c | else | [NH₃(CH₂)₄NH₃]PbCl₄ | 1 | 1,4-butyldiamine | — |
| P-1 | else | [C₆H₅(CH₂)₂NH₃]₂PbI₄ | 1 | Phenylethylammonium | — |
| P-1 | else | [C₆H₅(CH₂)₂NH₃]₂PbI₄ | 1 | Phenylethylammonium | — |
| P-1 | else | [CH₃C₆H₄(CH₂)₂NH₃]₂PbI₄ | 1 | p-methylphenylethylammonium | — |
| P-1 | else | [CH₃C₆H₄(CH₂)₂NH₃]₂PbI₄ | 1 | p-methylphenylethylammonium | — |
| C2/c | else | [BrC₆H₄(CH₂)₂NH₃]₂PbI₄ | 1 | p-bromophenylethylammonium | — |
| C2/c | else | [ClC₆H₄(CH₂)₂NH₃]₂PbI₄ | 1 | p-chlorophenylethylammonium | — |
| P21/c | else | [C₅H₄NH(CH₂)₂NH₃]PbI₄ | 1 | 2-(1-Pyridyl)ethylammonium | — |
| Pc | DJ | [C₅H₁₁NCH₂NH₃][CH₃NH₃]Pb₂Br₇ | 2 | 3-(aminomethyl)piperidinium | Methyl- |
| | | | | | ammonium |
| Cc | DJ | [C₅H₁₁NCH₂NH₃][CH₃NH₃]Pb₂Br₇ | 2 | 4-(aminomethyl)piperidinium | Methyl- |
| | | | | | ammonium |
| Cm | DJ | [C₅H₁₁NCH₂NH₃][CH(NH₂)₂]Pb₂Br₇ | 2 | 3-(aminomethyl)piperidinium | Form- |
| | | | | | amidinium |
| Pc | DJ | [C₅H₁₁NCH₂NH₃][CH(NH₂)₂]Pb₂Br₇ | 2 | 4-(aminomethyl)piperidinium | Form- |
| | | | | | amidinium |
| Cmc21 | RP | [CH₃(CH₂)₃NH₃]₂CsPb₂Br₇ | 2 | Butylammonium | Cs |
| Cmc21 | RP | [CH₃(CH₂)₃NH₃]₂CsPb₂Br₇ | 2 | Butylammonium | Cs |
| Cmca | RP | [CH₃(CH₂)₃NH₃]₂CsPb₂Br₇ | 2 | Butylammonium | Cs |
| Cmc21 | RP | [CH₃(CH₂)₃NH₃]₂[CH(NH₂)₂]Pb₂Br₇ | 2 | Butylammonium | Form- |
| | | | | | amidinium |
| Cmcm | RP | [CH₃(CH₂)₃NH₃]₂[CH(NH₂)₂]Pb₂Br₇ | 2 | Butylammonium | Form- |
| | | | | | amidinium |
| Cmc21 | else | [CH₃(CH₂)₃NH₃]₂[CH₃NH₃]₂Pb₃Br₁₀ | 3 | Butylammonium | Methyl- |
| | | | | | ammonium |
| Cmca | RP | [CH₃(CH₂)₃NH₃]₂[CH₃NH₃]₂Pb₃Br₁₀ | 3 | Butylammonium | Methyl- |
| | | | | | ammonium |
| Cmc21 | RP | [CH₃(CH₂)₃NH₃]₂(CH₃NH₃)Pb₂Br₇ | 2 | Butylammonium | Methyl- |
| | | | | | ammonium |
| Cmca | RP | [CH₃(CH₂)₃NH₃]₂(CH₃NH₃)Pb₂Br₇ | 2 | Butylammonium | Methyl- |
| | | | | | ammonium |
| Pnma | else | [CH₃(CH₂)₄NH₃]₂[CH(NH₂)₂]Pb₂I₇ | 2 | Pentylammonium | Form- |
| | | | | | amidinium |
| Cmc21 | else | [CH₂CHCH₂NH₃]₂[CH₃CH₂NH₃]₂Pb₃Br₁₀ | 3 | Allylammonium | Ethyl- |
| | | | | | ammonium |
| Fmmm | RP | [CH₂CHCH₂NH₃]₂[CH₃CH₂NH₃]₂Pb₃Br₁₀ | 3 | Allylammonium | Ethyl- |
| | | | | | ammonium |
| I4/mmm | RP | [CH₂CHCH₂NH₃]₂[CH₃CH₂NH₃]₂Pb₃Br₁₀ | 3 | Allylammonium | Ethyl- |
| | | | | | ammonium |
| Cmc21 | else | [F₂C₆H₉NH₃]₂PbI₄ | 1 | 4,4-difluorocyclohexyl- | — |
| | | | | ammonium | |
| Pbca | else | [F₂C₆H₉NH₃]₂PbI₄ | 1 | 4,4-difluorocyclohexyl- | — |
| | | | | ammonium | |
| Cmc21 | else | [CH₃CH₂NH₃]₂[CH₃NH₃]₂Pb₃Br₁₀ | 3 | Ethylammonium | Methyl- |
| | | | | | ammonium |
| I4/mmm | RP | [CH₃CH₂NH₃]₂[CH₃NH₃]₂Pb₃Br₁₀ | 3 | Ethylammonium | Methyl- |
| | | | | | ammonium |
| Pbca | RP | (HOOC(CH₂)₃NH₃)PbI₄ | 1 | ammonium 4-butyric acid | — |
| Aba2 | RP | (HOOC(CH₂)₃NH₃)₂(CH₃NH₃)Pb₂I₇ | 2 | ammonium 4-butyric acid | Methyl- |
| (C2cb) | | | | | ammonium |
| P21/c | else | [C₁₆H₉(CH₂)₂NH₃]₂PbI₄ | 1 | pyrene-butylammonium | — |
| Pbca | RP | [CH₃(CH₂)₃NH₃]₂PbBr₄ | 1 | Butylammonium | — |
| Aba2 | RP | [CH₃(CH₂)₃NH₃]₂[CH₃NH₃]₂Pb₃I₁₀ | 3 | Butylammonium | Methyl- |
| (C2cb) | | | | | ammonium |
| Ama2 | RP | [CH₃(CH₂)₃NH₃]₂[CH₃NH₃]₃Pb₄I₁₃ | 4 | Butylammonium | Methyl- |
| (Cc2m) | | | | | ammonium |
| P21 | else | [NH₃(CH₂)₂SS(CH₂)₂NH₃]PbBr₄ | 1 | 2,2′-dithiobisethan- | — |
| | | | | ammonium | |
| P21 | else | [NH₂(C₂H₄)₂NH₂]PbBr₄ | 1 | Piperazinium | — |
| Cmc21 | else | [C₆H₁₁NH₃]PbBr₄ | 1 | Cyclohexylammonium | — |
| Cmc21 | else | [C₆H₁₁NH₃]PbBr₄ | 1 | Cyclohexylammonium | — |
| P-1 | else | [C₆H₅NH₃]₂PbCl₄ | 1 | Phenylethylammonium | — |
| Pnma | else | [CH₃(CH₂)₂NH₃]₂PbCl₄ | 1 | Propylammonium | — |
| P21/c | DJ | [C(NH₂)₃]₂SnI₄ | 1 | Guanidinium | — |
| (P21/n) | | | | | |
| Pbca | RP | [I(CH₂)₆NH₃]₂PbI₄ | 1 | 6-iodohexylammonium | — |
| P-1 | else | [C₆H₉(CH₂)₂NH₃]₂PbI₄ | 1 | 2-(1-cyclohexenyl)ethyl- | — |
| | | | | ammonium | |
| P21/c | else | [C₆H₅CH(CH₃)NH₃]₂PbI₄ | 1 | 1-phenylethylammonium | — |
| (P21/a) | | | | | |
| P-1 | else | [(C₆H₅(CH₂)₂NH₃)₂(CH₃NH₃)]Pb₂I₇ | 2 | Phenylethylammonium | Methyl- |
| | | | | | ammonium |
| P1 | else | [ClC₆H₄CH₂(CH₃)NH₃]₂PbI₄ | 1 | R-1-(4-chlorophenyl)ethyl- | — |
| | | | | ammonium | |
| P-1 | else | [ClC₆H₄CH₂(CH₃)NH₃]₂PbI₄ | 1 | S-1-(4-chlorophenyl)ethyl- | — |
| | | | | ammonium | |
| P21/c | else | [ClC₆H₄CH₂(CH₃)NH₃]₂PbI₄ | 1 | rac-1-(4-chlorophenyl)ethyl- | — |
| | | | | ammonium | |
| Cc | else | [NH₃(CH₂)₂(CH₃)(CH₂)₃NH₃]PbBr₄ | 1 | 3-aminopyridinium | — |
| Pc | DJ | [(C₅H₁₁NCH₂NH₃)[CH(NH₂)₂]_{0.5}(CH₃NH₃)_{0.5}]Pb₂Br₇ | 2 | 4-(aminomethyl)piperidinium | Methyl- |
| | | | | | ammonium |
| Pc | DJ | [(C₅H₁₁NCH₂NH₃)[CH(NH₂)₂]_{0.5}(CH₃NH₃)_{0.5}]Pb₂Br₇ | 2 | 4-(aminomethyl)piperidinium | Methyl- |
| | | | | | ammonium |
| C2 | DJ | [(C₅H₁₁NCH₂NH₃)[CH(NH₂)₂]_{0.5}(CH₃NH₃)_{0.5}]Pb₂Br₇ | 2 | 3-(aminomethyl)piperidinium | Methyl- |
| | | | | | ammonium |
| Pc | DJ | [(C₅H₁₁NCH₂NH₃)[CH(NH₂)₂]Pb₂Br₇ | 2 | 4-(aminomethyl)piperidinium | Form- |
| | | | | | amidinium |
| Cc | DJ | [(C₅H₁₁NCH₂NH₃)(CH₃NH₃)]Pb₂Br₇ | 2 | 4-(aminomethyl)piperidinium | Methyl- |
| | | | | | ammonium |
| Cc | else | [C₆H₅(CH₂)₂NH₃]₂PbI₄ | 1 | Phenylethylammonium | — |
| P21/c | else | [C₅H₄NH(CH₂)₂NH₃]PbI₄ | 1 | 2-(1-Pyridyl)ethylammonium | — |
| (P21/n) | | | | | |
| P21/c | else | [C₃H₄N₂(CH₂)₂NH₃]PbI₄ | 1 | imidazolium | — |
| (P21/n) | | | | ethylammonium | |
| P21/c | RP | [CH₃CH(CH₃)CH₂NH₃]₂PbI₄ | 1 | Isobutylammonium | — |
| Cc | — | [CH₃CH(CH₃)CH₂NH₃]₂[CH₃NH₃]Pb₂I₇ | 2 | Isobutylammonium | Methyl- |
| | | | | | ammonium |
| Pbcn | RP | [C₆H₅CH₂NH₃]₂[CH₃NH₃]Pb₂I₇ | 2 | Phenylmethylammonium | Methyl- |
| | | | | | ammonium |
| Cmc21 | RP | [C₆H₅CH₂NH₃]₂[CH₃NH₃]₂Pb₃I₁₀ | 3 | Phenylmethylammonium | Methyl- |
| | | | | | ammonium |
| P1 | else | [C₆H₅CH(CH₃)NH₃]₂PbI₄ | 2 | R1-phenylethylammonium | — |
| P1 | else | [C₆H₅CH(CH₃)NH₃]₂PbI₄ | 2 | S1-phenylethylammonium | — |
| P21/c | else | [CH₃(CH₂)₂NH₃]₂[CH₃NH₃]₂Pb₃I₁₀ | 3 | Propylammonium | Methyl- |
| (P21/a) | | | | | ammonium |
| Cc | else | [CH₃(CH₂)₂NH₃]₂[CH₃NH₃]₃Pb₄I₁₃ | 4 | Propylammonium | Methyl- |
| | | | | | ammonium |
| Pc (Pn) | else | [C₅H₄NCH₂NH₃]PbI₄ | 1 | 3-(aminomethyl)piperidinium | — |
| Pc | else | [C₅H₄NCH₂NH₃][CH₃NH₃]Pb₂I₇ | 2 | 3-(aminomethyl)piperidinium | Methyl- |
| | | | | | ammonium |
| Cc | else | [C₅H₄NCH₂NH₃][CH₃NH₃]₂Pb₃I₁₀ | 3 | 3-(aminomethyl)piperidinium | Methyl- |
| | | | | | ammonium |
| Pc | else | [C₅H₄NCH₂NH₃][CH₃NH₃]₃Pb₄I₁₃ | 4 | 3-(aminomethyl)piperidinium | Methyl- |
| | | | | | ammonium |
| Pc (Pn) | DJ | [C₅H₄NCH₂NH₃]PbL₄ | 1 | 4-(aminomethyl)piperidinium | — |
| Cc | DJ | [C₅H₄NCH₂NH₃][CH₃NH₃]Pb₂I₇ | 2 | 4-(aminomethyl)piperidinium | Methyl- |
| | | | | | ammonium |
| Pc | DJ | [C₅H₄NCH₂NH₃][CH₃NH₃]₂Pb₃I₁₀ | 3 | 4-(aminomethyl)piperidinium | Methyl- |
| | | | | | ammonium |
| Pc | DJ | [C₅H₁₁NCH₂NH₃]PbI₄ | 1 | 4-(aminomethyl)piperidinium | — |
| P21/c | DJ | [C₅H₁₁NCH₂NH₃]PbI₄ | 1 | 4-(aminomethyl)piperidinium | — |
| Cc | else | [(CH₃(CH₂)₄NH₃)₂(CH₃NH₃)]Pb₂I₇ | 2 | Pentylammonium | Methyl- |
| | | | | | ammonium |
| Pc | else | [(CH₃(CH₂)₄NH₃)₂(CH₃NH₃)₂]Pb₃I₁₀ | 3 | Pentylammonium | Methyl- |
| | | | | | ammonium |
| Cc | else | [(CH₃(CH₂)₄NH₃)₂(CH₃NH₃)₃]Pb₄I₁₃ | 4 | Pentylammonium | Methyl- |
| | | | | | ammonium |
| Pc | else | [(CH₃(CH₂)₄NH₃)₂(CH₃NH₃)₄]Pb₅I₁₆ | 5 | Pentylammonium | Methyl- |
| | | | | | ammonium |
| Cc | else | [(CH₃(CH₂)₅NH₃)₂(CH₃NH₃)]Pb₂I₇ | 2 | Hexylammonium | Methyl- |
| | | | | | ammonium |
| Pc | else | [(CH₃(CH₂)₅NH₃)₂(CH₃NH₃)₂]Pb₃I₁₀ | 3 | Hexylammonium | Methyl- |
| | | | | | ammonium |
| Cc | else | [(CH₃(CH₂)₅NH₃)₂(CH₃NH₃)₃]Pb₄I₁₃ | 4 | Hexylammonium | Methyl- |
| | | | | | ammonium |
| P21/c | else | [CH₃(CH₂)₇NH₃]₂PbI₄ | 1 | Heptylammonium | — |
| Pbca | RP | [CH₃(CH₂)₇NH₃]₂PbI₄ | 1 | Heptylammonium | — |
| Pbca | RP | [CH₃(CH₂)₇NH₃]₂PbI₄ | 1 | Heptylammonium | — |
| P21/c | else | [CH₃(CH₂)₈NH₃]₂PbI₄ | 1 | Octylammonium | — |
| Pbca | RP | [CH₃(CH₂)₈NH₃]₂PbI₄ | 1 | Octylammonium | — |
| Cmca | RP | [CH₃(CH₂)₈NH₃]₂PbI₄ | 1 | Octylammonium | — |
| P21/c | else | [CH₃(CH₂)₉NH₃]₂PbI₄ | 1 | Nonylammonium | — |
| Pbca | RP | [CH₃(CH₂)₉NH₃]₂PbI₄ | 1 | Nonylammonium | — |
| P21/c | else | [CH₃(CH₂)₁₀NH₃]₂PbI₄ | 1 | Decylammonium | — |
| Pbca | RP | [CH₃(CH₂)₁₀NH₃]₂PbI₄ | 1 | Decylammonium | — |
| Pbca | RP | [CH₃(CH₂)₁₀NH₃]₂PbI₄ | 1 | Decylammonium | — |
| Pbca | RP | [CH₃(CH₂)₁₀NH₃]₂PbI₄ | 1 | Decylammonium | — |
| Pbca | RP | [CH₃(CH₂)₁₀NH₃]₂PbI₄ | 1 | Decylammonium | — |
| P21/c | else | [FC₆H₄(CH₂)₂NH₃]₂PbI₄ | 1 | 4-fluorophenylethylammonium | — |
| C2/c | else | [ClC₆H₄(CH₂)₂NH₃]₂PbI₄ | 1 | p-chlorophenylethylammonium | — |
| Cmca | RP | [BrC₆H₄(CH₂)₂NH₃]₂PbI₄ | 1 | p-bromophenylethylammonium | — |
| C2/c | else | [C₂H₄N₃]₂PbBr₄ | 1 | 1,2,4-triazolium | — |
| C2/c | else | [C₂H₄N₃]₂PbBr₄ | 1 | 1,2,4-triazolium | — |
| P21/c | else | [C₂H₇N₂]₂PbBr₄ | 1 | Acetamidinium | — |
| P21/c | DJ | [C₂H₇N₂]₂PbBr₄ | 1 | Acetamidinium | — |
| Pbca | else | [C₇H₁₀N]₂PbI₄ | 1 | Phenylmethylammonium | — |
| P21/c | else | [C₇H₉FN]₂PbI₄ | 1 | 4-fluorophenylmethylammonium | — |
| P21 | else | [C₇H₉ClN]₂PbI₄ | 1 | 4-chlorophenylmethylammonium | — |
| P21 | else | [C₇H₉BrN]₂PbI₄ | 1 | 4-bromophenylmethylammonium | — |
| P21/c | else | [C₈H₉F₃N]₂PbI₄ | 1 | p-trifluoromethylphenyl- | — |
| | | | | methylammonium | |
| P-1 | else | (C₈H₁₂N)₂(CH₆N)Pb₂I₇ | 2 | Phenylethylammonium | Methyl- |
| | | | | | ammonium |
| C21/c | DJ | [C₁₂H₁₄N]₂PbBr₄ | 1 | 1-(1-naphthyl)ethylammonium | — |
| P21 21 21 | else | [C₈H₁₂N]₂PbI₄ | 1 | 1-phenylethylammonium | — |
| P21 21 21 | else | [C₈H₁₂N]₂PbI₄ | 1 | 1-phenylethylammonium | — |
| P 21 | else | [C₁₂H₁₄N]₂PbBr₄ | 1 | S-1-(1-naphthyl)ethylammonium | — |
| P21 21 21 | else | [C₈H₁₂N]₂PbI₄ | 1 | R-1-(1-naphthyl)ethylamine | — |
| P 21 | else | [C₁₂H₁₄N]₂PbBr₄ | 1 | 1-phenylethylammonium | — |
| Pbcn | else | [C₁₅H₂₀NO₂]₂PbI₄ | 1 | naphthalene-based | — |
| | | | | organic layers | |
| Pbca | RP | [C₁₃H₁₆NO₂]₂PbI₄ | 1 | naphthalene-based | — |
| | | | | organic layers | |
| Pca21 | else | [C₁₄H₁₈NO]₂PbI₄ | 1 | naphthalene-based | — |
| | | | | organic layers | |
| P21/c | else | [C₁₆H₂₂NO]₂PbI₄ | 1 | naphthalene-based | — |
| | | | | organic layers | |
| P-1 | else | [C₁₇H₂₄NO₂]₂PbI₄ | 1 | naphthalene-based | — |
| | | | | organic layers | |
| P21/c | else | [C₉H₉C₁₅NO]₂PbI₄ | 1 | tetrachloro-1,2-benzoquinone | — |
| Pmn21 | else | [CH₃NH₃]₂Pb(SCN)₂I₂ | 1 | Methylammonium | — |
| Pmn21 | else | [CH₃NH₃]₂Pb(SCN)₂I₂ | 1 | Methylammonium | — |
| Pmmn | else | [CH₃NH₃]₂Pb(SCN)₂I₂ | 1 | Methylammonium | — |
| Pnma | DJ | [C₈H₁₂N]₂SnI₄ | 1 | R-methylbenzylammonium | — |
| P21 21 21 | DJ | [C₈H₁₂N]₂SnI₄ | 1 | S-methylbenzylammonium | — |
| P 21 21 21 | DJ | [C₈H₁₂N]₂SnI₄ | 1 | Rac-methylbenzylammonium | — |
| P 21 | else | [C₆H₁₂F₂N]₂PbI₄ | 1 | 4-fluorohexahydroazepine | — |
| Cmc21 | else | [C₆H₁₂F₂N]₂PbI₄ | 1 | 4-fluorohexahydroazepine | — |
| Imm2 | RP | [C₆H₁₂F₂N]₂PbI₄ | 1 | 4-fluorohexahydroazepine | — |
| I-4m2 | RP | [C₆H₁₂F₂N]₂PbI₄ | 1 | 4-fluorohexahydroazepine | — |
| P21/c | else | [C₄H₁₃N₅]PbBr₄ | 1 | N,N-dimethylbiguanidinium | — |
| Cmc21 | else | (C₂H₈N)₂(C₄H₁₂N)₂Pb₃I₁₀ | 3 | Butylammonium | Ethyl- |
| | | | | | ammonium |
| Cc | else | (BA)₂(EAₓMA₁₋ₓ)₂Pb₃I₁₀ | 3 | Butylammonium | Ethyl- |
| | | | | | ammonium, |
| | | | | | Methyl- |
| | | | | | ammonium |
| Cc | RP | (BA)₂(EAₓMA₁₋ₓ)₂Pb₃I₁₀ | 3 | Butylammonium | Ethyl- |
| | | | | | ammonium, |
| | | | | | Methyl- |
| | | | | | ammonium |
| Cc | RP | (BA)₂(EA)₂Pb₃I₁₀ | 3 | Butylammonium | Ethyl- |
| | | | | | ammonium |
| C2/m | else | PEA₂PbI₄ | 1 | Phenylethylammonium | — |
| P-1 | else | PEA₂PbI₄ | 1 | Phenylethylammonium | — |
| P-1 | else | PEA₂MA₂Pb₃I₁₀ | 3 | Phenylethylammonium | — |
| P-1 | else | PEA₂MAPb₂I₇ | 2 | Phenylethylammonium | — |
| P-1 | else | PEA₂PbI₄ | 1 | Phenylethylammonium | — |
| Cmcm | RP | (BA)₂(FA)Pb₂I₇ | 2 | Butylammonium | Form- |
| | | | | | amidinium |
| Cmca | RP | (BA)₂(DMA)Pb₂I₇ | 2 | Butylammonium | Dimethyl- |
| | | | | | ammonium |
| Cmcm | RP | (BA)₂(GA)Pb₂I₇ | 2 | Butylammonium | Guanidinium |
| Ama2 | RP | (BA)₂(FA)Pb₂I₇ | 2 | Butylammonium | Form- |
| | | | | | amidinium |
| Aba2 | RP | (BA)₂(DMA)Pb₂I₇ | 2 | Butylammonium | Dimethyl- |
| | | | | | ammonium |
| Ama2 | RP | (BA)₂(GA)Pb₂I₇ | 2 | Butylammonium | Guanidinium |
| P21/c | else | (C₅H₁₁NH₃)₂(CH₃NH₂CH₃)Pb₂I₇ | 2 | C5H11NH3 | Dimethyl- |
| | | | | | ammonium |
| Cmcm | else | [C₈H₁₁FN]₂PbBr₄ | 1 | 3-fluoro-N-methylbenzyl- | — |
| | | | | ammonium | |
| Aba2 | RP | [C₅H₁₀F₂N]₂PbI₄ | 1 | 4,4-difluoropiperidinium | — |
| Cmca | RP | [C₆H₁₄N]₂PbBr₄ | 1 | Cyclohexylammonium | — |
| Cmca | RP | [C₆H₁₄N]₂PbI₄ | 1 | Cyclohexylammonium | — |
| Cmc21 | else | [C₅H₁₂ON]₂PbBr₄ | 1 | tetrahydropyranylammonium | — |
| Cmc21 | RP | [C₆H₁₆N]₂PbI₄ | 1 | Hexylammonium | — |
| Cmc21 | else | [C₇H₉FN]₂PbCl₄ | 1 | 2-fluorobenzylammonium | — |
| Cmc21 | else | [C₇H₁₀N]₂PbCl₄ | 1 | Phenylmethylammonium | — |
| Cmc21 | RP | [C₁₄H₁₆N]₂PbI₄ | 1 | 2-(4-biphenyl)ethylammonium | — |
| Pbcn | else | [C₇H₉FN]₂PbI₄ | 1 | 4-fluoro-N-methylanilinium | — |
| Pbcn | else | [C₈H₁₁FN]₂PbBr₄ | 1 | 3-fluoro-N-methylbenzyl- | — |
| | | | | ammonium | |
| Pbcn | else | [C₈H₁₁ClN]₂PbI₄ | 1 | 3-chloro-N-methylbenzyl- | — |
| | | | | ammonium | |
| Pbcn | else | [C₈H₁₁BrN]₂PbCl₄ | 1 | 3-bromo-N-methylbenzyl- | — |
| | | | | ammonium | |
| Pbcn | else | [C₈H₁₁BrN]₂PbBr₄ | 1 | 3-bromo-N-methylbenzyl- | — |
| | | | | ammonium | |
| Pnma | else | [C₃H₇N₂]₂PbI₄ | 1 | 2-cyanoethylammonium | — |
| Pnma | DJ | [C₅H₅BrN]₂PbBr₄ | 1 | 3-bromopyridinium | — |
| Pnma | else | [C₇H₉FN]₂PbCl₄ | 1 | 4-fluorobenzylammonium | — |
| Pnma | else | [C₈H₂₀N₂]PbCl₄ | 1 | 1,4-cyclohexanedimethyl- | — |
| | | | | ammonium | |
| Pbcm | else | [C₂H₁₀N₂]PbI₄ | 1 | 1,2-ethanediammonium | — |
| Pbca | RP | [C₄H₁₂N]₂PbCl₄ | 1 | Butylammonium | — |
| Pbca | RP | [C₅H₈SN]₂PbCl₄ | 1 | 2-thiophenemethylammonium | — |
| Pbca | RP | [C₅H₈SN]₂PbBr₄ | 1 | 2-thiophenemethylammonium | — |
| Pbca | else | [C₁₀H₁₆N]₂PbBr₄ | 1 | Deca-3,5-diyn-1-ammonium | — |
| Cc | else | [C₆H₁₈N₂]PbBr₄ | 1 | 2-Methylpentane-1,5-di- | — |
| | | | | ammonium | |
| Pca21 | RP | [C₁₆H₃₆N]₂PbI₄ | 1 | Hexadecylammonium | — |
| Pca21 | else | [C₁₄H₁₈ON]₂PbI₄ | 1 | 4-[(Naphthalen-1- | — |
| | | | | yl)oxy]butyl-1-ammonium | |
| P21/c | RP | [C₄H₁₂N]₂PbBr₄ | 1 | Butylammonium | — |
| P212121 | else | [C₃H₁₂N₂]PbCl₄ | 1 | 1,3-propyldiammonium | — |
| P212121 | else | [C₈H₁₂N]₂PbI₄ | 1 | 1-phenylethylammonium | — |
| Pn | else | [C₇H₉FN]₂PbI₄ | 1 | 3-fluoro-N-methylanilinium | — |
| P21/c | else | [C₄H₁₄S₂N₂]PbCl₄ | 1 | 2,2′-Dithiobis(ethylammonium) | — |
| P21/c | else | [C₆H₁₆N₂]PbI₄ | 1 | 4-(aminomethyl)piperidinium | — |
| P21/c | else | [C₆H₁₈N₂]PbCl₄ | 1 | 1,6-hexanediammonium | — |
| P21/n | else | [C₅H₁₂O₂N]₂PbBr₄ | 1 | 5-carboxipentylammonium | — |
| P21/n | else | [C₇H₉FN]₂PbI₄ | 1 | 4-fluorobenzylammonium | — |
| C2/c | else | [C₅H₁₂N]₂PbCl₄ | 1 | Piperidinium | — |
| C2/c | else | [C₂₀H₂₀S₄N]₂PbI₄ | 1 | 2-(3″′,4′-dimethyl- | — |
| | | | | [2,2′:5′,2″:5″,2″′- | |
| | | | | quaterthiophen]-5-yl)ethan- | |
| | | | | 1-ammonium | |
| Pnma | else | [C₅H₁₂N]₂PbBr₄ | 1 | Piperidinium | — |
| Pbnm | else | [C₂H₇ClN]₂PbI₄ | 1 | 2-chloroethylammonium | — |
| P21/n | else | [C₇H₁₂N₂]PbBr₄ | 1 | 2-(4-Pyridyl)ethylammonium | — |
| P21/n | else | [C₇H₁₂N₂]PbI₄ | 1 | 2-(2-Pyridyl)ethylammonium | — |
| P21/n | else | [C₇H₁₂N₂]PbI₄ | 1 | 2-(3-Pyridyl)ethylammonium | — |
| P21/n | else | [C₇H₁₂N₂]PbI₄ | 1 | 2-(4-Pyridyl)ethylammonium | — |
| Cc | else | [C₇H₁₀N]₂PbI₄ | 1 | N-methylanilinium | — |
| P21/c | — | FA₂PbBr₄ | 1 | Formamidinium | — |
| Pbam | — | [C₁₁H₁₂N]₂PbCl₄ | 1 | 1-(2-Naphthyl)-methylammonium | — |
| P21/a | else | [C₈H₁₂N]₂PbCl₄ | 1 | 4-methylbenzylammonium | — |
| P21/a | else | [C₈H₁₂N]₂PbBr₄ | 1 | 4-methylbenzylammonium | — |
| P21/a | else | [C₈H₁₂N]₂PbI₄ | 1 | 4-methylbenzylammonium | — |
| P21/a | RP | [C₈H₁₂ON]₂PbI₄ | 1 | 4-Methoxy-N-methylanilinium | — |
| P21/c | else | [C₆H₇ClN]₂PbI₄ | 1 | 4-Chloroanilinium | — |
| P21/c | else | [C₆H₇ClN]₂PbI₄ | 1 | 4-Bromoanilinium | — |
| P21/c | else | [C₈H₁₀Cl₂N]₂PbI₄ | 1 | 2-(3,5-Dichlorophenyl)ethyl-1- | — |
| | | | | ammonium | |
| P21/c | else | [C₈H₁₀Br₂N]₂PbI₄ | 1 | 2-(3,5-Dibromophenyl)ethyl-1- | — |
| | | | | ammonium | |
| P21/c | else | [C₁₀H₁₆N]₂PbI₄ | 1 | 2-(3,5-Dimethylphenyl)ethyl-1- | — |
| | | | | ammonium | |
| P21 | else | [C₈H₁₁BrN]₂PbI₄ | 1 | 2-bromophenylethylammonium | — |
| P-1 | else | [C₅H₁₂O₂N]₂PbCl₄ | 1 | 4-carboxibutylammonium | — |
| P-1 | else | [C₁₂H₁₈S₄N₂]PbI₄ | 1 | 2-([2,2′-bithiophen]-5- | — |
| | | | | yl)ethyl-1-ammonium | |
| Pna21 | — | [C₄₀H₄₈N₄S₁₂]Pb₃I₁₀ | 1 | 5,5′-bis(ammoniumethyl- | — |
| | | | | sulfanyl)-2,2′-bithiophene | |
| P212121 | — | [C₃₀H₃₆N₃S₉]Bi₂I₉ | 1 | 2-([2,2′-bithiophen]-5- | — |
| | | | | yl)ethyl-1-ammonium | |
| P21 | DJ | [C₅H₁₆PN]PbBr₄ | 1 | (2-Azaniumylethyl)trimethyl- | — |
| | | | | phosphonium | |
| C2/c | else | [C₅H₁₁N₃]PbBr₄ | 1 | 4-(2-aminoethyl)imidazolium | — |
| P21/c | else | [C₅H₁₁N₃]PbBr₄ | 1 | 2-(2-aminoethyl)imidazolium | — |
| P21/c | else | [C₅H₁₅N₂]PbCl₄ | 1 | N-methylethane-1,2-diammonium | — |
| P21212 | DJ | [C₆H₁₆N₂]PbI₄ | 1 | Cyclohexane-1,2-diammonium | — |
| P-1 | else | [C₉H₁₄ON]₂PbI₄ | 1 | 2-(4-Methoxyphenyl)ethyl-1- | — |
| | | | | ammonium | |
| P1 | else | [C₁₀H₁₂S₂N]₂PbI₄ | 1 | 2-([2,2′-bithiophen]-5- | — |
| | | | | yl)ethyl-1-ammonium | |
| P-1 | else | [C₂₄H₂₂S₄N]₂PbI₄ | 1 | 5,5″′-bis-(aminoethyl)- | — |
| | | | | 2,2′:5′,2″:5″,2″′-quaterthiophene | |
| Pbca | else | [C₅H₁₆N₂]PbI₄ | 1 | N,N′-dimethylpropane- | — |
| | | | | 1,3-diammonium | |
| Pbca | else | [C₆H₁₇N₃]PbI₄ | 1 | 1-(2-Aminoethyl)piperazinium | — |
| Pbca | else | [C₇H₁₂N₂]PbBr₄ | 1 | 2-(3-Pyridyl)ethylammonium | — |
| Pbca | else | [C₉H₁₄N]₂PbBr₄ | 1 | Phenylpropylammonium | — |
| Pmnm | else | [CH₃NH₂NH₂]PbBr₄ | 1 | Methylhydrazinium | — |
| Pmnm | — | [CH₃NH₂NH₂]PbBr₄ | 1 | Methylhydrazinium | — |
| Pmn21 | else | [CH₃NH₂NH₂]PbBr₄ | 1 | Methylhydrazinium | — |
| Pmn21 | else | [CH₃NH₂NH₂]PbBr₄ | 1 | Methylhydrazinium | — |
| P21 | else | [HOOC(CH₂)₆NH₃]₄Pb₃I₁₀ | 1 | cis-4-aminocyclohexanecar- | — |
| | | | | boxylic acid | |
| C2/c | else | [HOOC(CH₂)₆NH₃]PbI₄ | 1 | trans-4-aminocyclohexane- | — |
| | | | | carboxylic acid | |
| Cc | else | (CH₃(CH₂)₅NH₃)₂(CH₃NH₃)Pb₂Br₇ | 2 | Hexylammonium | Methyl- |
| | | | | | ammonium |
| C2/c | RP | (CH₃(CH₂)₅NH₃)₂(CH₃NH₃)Pb₂Br₇ | 2 | Hexylammonium | Methyl- |
| | | | | | ammonium |
| Cc | RP | (CH₃(CH₂)₆NH₃)₂(CH₃NH₃)Pb₂Br₇ | 2 | Heptylammonium | Methyl- |
| | | | | | ammonium |
| Cc | RP | (CH₃(CH₂)₇NH₃)₂(CH₃NH₃)Pb₂Br₇ | 2 | Octylammonium | Methyl- |
| | | | | | ammonium |
| Cc | else | (CH₃(CH₂)₇NH₃)₂(CH₃NH₃)Pb₂I₇ | 2 | Octylammonium | Methyl- |
| | | | | | ammonium |
| P21/c | else | [C₈H₁₁S₂(CH₂)₃NH₃]₂PbI₄ | 1 | 2,2′-bithiophene | — |
| P21/c | else | [C₈H₁₁S₂(CH₂)₃NH₃]₂PbBr₄ | 1 | 3-([2,2′-bithiophen]-5- | — |
| | | | | yl)propan-1-ammonium | |
| P21/c | else | [C₈H₁₁S₂(CH₂)₃NH₃]₂PbCl₄ | 1 | 3-([2,2′-bithiophen]-5- | — |
| | | | | yl)propan-1-ammonium | |
| P21/c | DJ | [C₈H₁₁S₂(CH₂)₃NH₃]₁₂Pb₉I₃₀ | 1 | 3-([2,2′-bithiophen]-5- | — |
| | | | | yl)propan-1-ammonium | |
| P21/c | else | [C₈H₁₁S₂(CH₂)₃NH₃]₄Pb₃I₁₀ | 1 | 3-([2,2′-bithiophen]-5- | — |
| | | | | yl)propan-1-ammonium | |
| Cc | else | [(CH₃)₃CNH₃]₂[CH₃NH₃]Pb₂Br₇ | 2 | Isobutylammonium | Methyl- |
| | | | | | ammonium |
| Ccc2 | RP | [CH₃(CH₂)₃NH₃]₂[CH₃NH₃]Pb₂Br₈ | 2 | Butylammonium | Methyl- |
| | | | | | ammonium |
| Ccc2 | RP | [CH₃(CH₂)₄NH₃]₂[CH₃NH₃]Pb₂Br₇ | 2 | Pentylammonium | Methyl- |
| | | | | | ammonium |
| P21/c | else | [NH₃CH₂C₆H₄F₄CH₂NH₃]₂PbI₄ | 1 | 2,3,5,6-tetrafluoro-1,4- | — |
| | | | | phenylenedimethanammonium | |
| P1 | else | [C₅H₁₂NO]₂PbBr₄ | 1 | tetrahydropyranylammon | — |
| R3 | else | (COOH(CH₂)NH₂)PbI₂ | 1 | (2-carboxy)methylammonium | — |
| Pbca | RP | (COOH(CH₂)₃NH₃)₂PbI₄ | 1 | (2-carboxy)ethylammonium | — |
| P21/c | else | (COOH(CH₂)₇NH₃)₂PbI₄ | 1 | (2-carboxy)butylammonium | — |
| P2(1)/c | else | (COOH(CH₂)₉NH₃)₂PbI₄ | 1 | (2-carboxy)butylammonium | — |
| P-1 | else | [C₂₂H₂₀N₃S₄]₂PbI₄ | 1 | 2-[5-[4-methyl-5-[7-(3- | — |
| | | | | methylthiophen-2-yl)- | |
| | | | | 2,1,3-benzothiadiazol-4- | |
| | | | | yl]thiophen-2- | |
| | | | | yl]thiophen-2- | |
| | | | | yl]ethylammonium | |
| Pbca | else | [CH₃(CH₂)₃NH₃]₂PbI₄ | 1 | Butylammonium | — |
| Pbca | else | [CH₃(CH₂)₃NH₃]₂PbI₄ | 1 | Butylammonium | — |
| Pbca | RP | [CH₃(CH₂)₃NH₃]₂PbI₄ | 1 | Butylammonium | — |
| P42/mnm | RP | [CH₃(CH₂)₃NH₃]₂ [CH₃NH₃]Pb₂I₇ | 2 | Butylammonium | Methyl- |
| | | | | | ammonium |
| P-1 | else | [C₆H₅(CH₂)₂NH₃]₂PbI₄ | 1 | Phenylethylammonium | — |
| P-2 | else | [C₆H₅(CH₂)₂NH₃]₂PbI₄ | 1 | Phenylethylammonium | — |
| P-3 | else | [C₆H₅(CH₂)₂N₃]₂PbI₄ | 1 | Phenylethylammonium | — |
| P21 | DJ | [(CH₃)₃N(CH₂)₂NH₃]PbBr₄ | 1 | 2-trimethylammoniumethyl- | — |
| | | | | ammonium | |
| P22 | DJ | [(CH₃)₃P(CH₂)₂NH₃]PbBr₄ | 1 | (2-aminoethyl)trimethyl- | — |
| | | | | phosphanium | |
| P23 | DJ | [(CH₃)₃P(CH₂)₂NH₃]PbBr₄ | 1 | (2-aminoethyl)trimethyl- | — |
| | | | | phosphanium | |
| P-1 | else | [CH₃OC₆H₄(CH₂)₂NH₃]₂PbI₄ | 1 | Methoxyphenethylammonium | — |
| P21/c | else | [CH₃O(C₂H₄)(CH₂)₂NH₃]₂PbCl₄ | 1 | 2-(6-ethoxy-1,2,4,5-tetrazin- | — |
| | | | | 3-yl)oxyethylammonium | |
| Pbca | RP | [CH₃O(CH₂)₃NH₃]₂PbBr₄ | 1 | γ-Methoxypropylammonium | — |
| P-1 | else | [₃-FC₆H₄CH₂CH₂NH₃]₂PbI₄ | 1 | 2-(3-fluorophenyl)ethyl- | — |
| | | | | ammonium | |
| P-1 | else | [NH₃CH₂C₆F₄CH₂NH₃]₂PbI₄ | 1 | 2,3,5,6-tetrafluoro-1,4- | — |
| | | | | benzenediammonium | |
| P21/c | else | [(CH₃)₂NHC₆H₄NH(CH₃)₂]₂PbBr₄ | 1 | N,N,N′,N′-Tetramethyl- | — |
| | | | | p-phenylenediammonium | |
| Cmmm | else | [HSC(NH₂)₂][CH₃NH₃]₂Pb₂I₇ | 2 | Protonated thiourea cation | — |
| Imma | else | [HSC(NH₂)₂][CH₃NH₃]₃Pb₃I₁₀ | 3 | Protonated thiourea cation | — |
| Imma | else | [HSC(NH₂)₂][CH₃NH₃]PbI₄ | 1 | Protonated thiourea cation | — |
| P21/c | else | [C₅H₁₀N(CH₂)₂NH₃]PbI₄ | 1 | 2-(aminoethyl)piperidinium | — |
| P21/n | else | [C₅H₁₀N(CH₂)₂NH₃]PbI₄ | 1 | 2-(aminoethyl)piperidinium | — |
| Cc | else | [CH₃(CH₂)₄NH₃]₂[CH₃NH₃]₄Pb₅I₁₆ | 6 | Pentylammonium | Methyl- |
| | | | | | ammonium |
| Pm | else | [COOHC₆H₁₀CH₂NH₃]₂[CH₃CH₂NH₃]Pb₃Br₁₀ | 3 | 4-Aminomethyl-1- | Ethyl- |
| | | | | cyclohexanecarboxylate | ammonium |
| Pmmn | else | [COOHC₆H₁₀CH₂NH₃]₂[CH₃CH₂NH₃]Pb₃Br₁₀ | 3 | 4-Aminomethyl-1- | Ethyl- |
| | | | | cyclohexanecarboxylate | ammonium |
| Pmmn | else | [COOHC₆H₁₀CH₂NH₃]₂[CH₃CH₂NH₃]Pb₃Br₁₀ | 3 | 4-Aminomethyl-1- | Ethyl- |
| | | | | cyclohexanecarboxylate | ammonium |
| Cmcm | else | [COOHC₆H₁₀CH₂NH₃]₂[CH₃CH₂NH₃]Pb₃Br₁₀ | 3 | 4-Aminomethyl-1- | Ethyl- |
| | | | | cyclohexanecarboxylate | ammonium |
| Cmc21 | RP | [Br(CH₂)₃NH₃]₂[CH(NH₂)₂]Pb₂Br₇ | 2 | 3-bromopropylammonium | Form- |
| | | | | | amidinium |
| Cmcm | RP | [Br(CH₂)₃NH₃]₂[CH(NH₂)₂]Pb₂Br₇ | 2 | 3-bromopropylammonium | Form- |
| | | | | | amidinium |
| Cmcm | RP | [Br(CH₂)₃NH₃]₂[CH(NH₂)₂]Pb₂Br₇ | 2 | 3-bromopropylammonium | Form- |
| | | | | | amidinium |
| Pmc21 | RP | [Br(CH₂)₃NH₃]₂[CH(NH₂)₂]Pb₂Br₇ | 2 | 3-bromopropylammonium | Form- |
| | | | | | amidinium |
| Pmc21 | DJ | [NH₃C₆H₄NH₃][CH(NH₂)₂]₂Pb₃I₁₀ | 3 | m-phenylenediammonium | Form- |
| | | | | | amidinium |
| Cc | else | [NH₃C₆H₄NH₃]₂PbI₄ | 1 | m-phenylenediammonium | Form- |
| | | | | | amidinium |
| Pc | DJ | [NH₃C₆H₄NH₃][CH(NH₂)₂]Pb₂I₇ | 2 | m-phenylenediammonium | Form- |
| | | | | | amidinium |
| C2/m | else | [IC₄₈NH₃]₂[CH₃NH₃]₂Pb₃I₁₀ | 3 | 4-iodobutylammonium | Methyl- |
| | | | | | ammonium |
| Pc | else | [IC₄₈NH₃]₂[CH₃NH₃]₂Pb₃I₁₀ | 3 | 4-iodobutylammonium | Methyl- |
| | | | | | ammonium |
| Pca21 | else | (C₂H₆N₂, CH₃NH₃)PbI₄ | 1 | Acetamidinium | Methyl- |
| | | | | | ammonium |
| P212121 | else | [C₉H₁₄N]₂PbBr₄ | 1 | Phenyl-2-methylethylammonium | — |
| P21 | else | [C₉H₁₄N, C₃H₁₀N]PbBr₄ | 1 | Phenyl-2-methylethylammonium | — |
| P21 | else | [C₉H₁₄N, C₄H₁₂N]PbBr₄ | 1 | Phenyl-2-methylethylammonium, | — |
| | | | | Butylammonium | |
| P21 | else | [C₉H₁₄N, C₄H₁₂N]PbBr₄ | 1 | Phenyl-2-methylethylammonium, | — |
| | | | | Butylammonium | |
| P21 | else | [C₉H₁₄N, C₃H₁₀N]PbBr₄ | 1 | Phenyl-2-methylethylammonium, | — |
| | | | | Propylammonium | |
| P21/m | else | [C₁₀H₁₈N₂]PbBr₄ | 1 | N,N,N′,N′-tetramethyl- | — |
| | | | | 1,4-phenylenediammonium | |
| P21/c | else | I₄Sn•₂(C₂₂H₂₀NS₅)•C₇H₈ | 1 | Thienothiophene | — |
| Cc | else | I₄Sn•₂(C₂₂H₂₀NS₅)•CH₂Cl₂ | 1 | Thienothiophene | — |
| P21/c | else | ₂(C₂₂H₂₀NS₅)•I₄Sn•C₆H₅Cl | 1 | Thienothiophene | — |
| C2/c | else | ₂(C₂₄H₂₀NS₆)•I₄Sn | 1 | Dithienothiophene | — |
| I4/mmm | RP | [₄-Cl-₂-FBA]PbBr₄ | 1 | 4-Chloro-2- | — |
| | | | | fluorobenzylammonium | |
| Pnma | else | [₄-Cl-₂-FBA]PbBr₄ | 1 | 4-Chloro-2- | — |
| | | | | fluorobenzylammonium | |
| P-1 | else | [NH₃C₄H₈NH₃]₂PbI₄ | 1 | 1,4-butanediammonium | — |
| P-1 | else | (₃Me-PEA)₂PbI₄ | 1 | 2-(3-Methylphenyl)ethyl- | — |
| | | | | ammonium | |
| P-1 | else | [PDAPbI₄]₁₅•[PDAI₂] | 1 | 1,3-propanediammonium | — |
| P21/c | else | (DMePDA)PbI₄ | 1 | N,N-dimethylpropane- | — |
| | | | | 1,3-diammonium | |
| I4/mmm | RP | (i-BA)₂(DMA)Pb₂Br₇ | 2 | Isobutylammonium | — |
| P21/c | DJ | (PDMA)PbI₄ | 1 | 1,4-phenylenedimethan- | — |
| | | | | ammonium | |
| P4/mbm | DJ | (PDMA)(MA)Pb₂I₇ | 2 | 1,4-phenylenedimethan- | — |
| | | | | ammonium | |
| I4/mcm | DJ | (PDMA)(MA)Pb₂I₇ | 2 | 1,4-phenylenedimethan- | — |
| | | | | ammonium | |
| Pbcn | else | (DFP)₂PbI₄ | 1 | 3,3-difluoropyrrolidinium | — |
| P212121 | DJ | (DFP)₂PbI₄ | 1 | 3-fluoropyrrolidinium | — |
| Pmmn | — | Cs₂Pb(SCN)₂Br₂ | 1 | Caesium | — |
| P21/c | else | (₃AMPY)(FA)Pb₂I₇ | 2 | 3-(aminomethyl)pyridinium | — |
| Cmc21 | else | (PTEA)₂PbI₄ | 1 | 1-(p-tolyl)ethylammonium | — |
| P1 | else | [(R)MPA]₂PbI₄ | 1 | β-methylphenethylammonium | — |
| P1 | else | [(S)-MPA]₂PbI₄ | 1 | β-methylphenethylammonium | — |
| P212121 | else | L₄Sn•C₁₅H₁₁N₂S₂•C₁₅H₁₃N₂S₂•C₆H₄Cl₂ | 1 | 2-(5-(thiophen-2-yl)thiophen- | — |
| | | | | 2-yl)acetamidinium, DCB | |
| C2 | else | R-[BPEA]₂PbI₄ | 1 | R-1-(4- | — |
| | | | | bromophenyl)ethylaminium | |
| C2 | else | S-[BPEA]₂PbI₄ | 1 | S-1-(4- | — |
| | | | | bromophenyl)ethylaminium | |
| P21/c | else | S-[BPEA]₂PbI₄ | 1 | S-1-(4- | — |
| | | | | bromophenyl)ethylaminium | |
| Cmc21 | else | BA₂EA₂Pb₃I₁₀ | 3 | Butylammonium | Ethyl- |
| | | | | | ammonium |
| I4/mmm | RP | BA₂EA₂Pb₃I₁₀ | 3 | Butylammonium | Ethyl- |
| | | | | | ammonium |
| Cmmm | — | Cs₂[C(NH₂)₃]Pb₂Br₇ | 2 | Guanidinium | Cs |
| P-1 | else | (₃AP)PbI₄ | 1 | 3-amidinopyridinium | — |
| C2/c | else | (₃AP)PbBr₄ | 1 | 3-amidinopyridinium | — |
| C2/c | else | (₃AP)PbCl₄ | 1 | 3-amidinopyridinium | — |
| P21/c | RP | (PA)PbI₄ | 1 | Propylammonium | — |
| P21/c | RP | (AA)₂MA₂Pb₃I₁₀ | 3 | Allylammonium | Methyl- |
| | | | | | ammonium |
| P21/c | else | (IdPA)₂MA₂Pb₃I₁₀ | 3 | 2-iodopropylammonium | Methyl- |
| | | | | | ammonium |
| Cc | RP | [(AA)ₓ(IdPA)₁-ₓ]₂MAPb₂I₇ | 2 | Allylammonium | 2-iodopropyl- |
| | | | | | ammonium |
| P21/c | else | (IdPA)₂PbI₄ | 1 | 2-iodopropylammonium | — |
| P21/c | else | (AA)₂MA₂Pb₃I₁₀ | 3 | Allylammonium | Methyl- |
| | | | | | ammonium |
| P-1 | DJ | (AA)₁₂(MA)₂Pb₉I₃₂ | 2 | Allylammonium | Methyl- |
| | | | | | ammonium |
| P212121 | else | (AA)₃Pb₂I₇ | 1 | Allylammonium | — |
| C2/c | else | (IdPA)₂MAPb₂I₇ | 2 | 2-iodopropylammonium | Methyl- |
| | | | | | ammonium |
| P21212 | else | (R)-C₆H₁₆N₂PbBr₄ | 1 | (1R, 2R)-(−)-1,2- | — |
| | | | | Cyclohexanediammonium | |
| P21212 | else | (S)-C₆H₁₆N₂PbBr₄ | 1 | (1S, 2S)-(+)-1,2- | — |
| | | | | Diaminocyclohexane | |
| Pbca | RP | (C₁₁H₂₃NH₃)₂PbI₄ | 1 | Undecylammonium | — |
| P212121 | else | (C₁₁H₂₃NH₃)₂PbI₄ | 1 | Undecylammonium | — |
| Pbca | RP | (C₁₁H₂₃NH₃)₂PbI₄ | 1 | Undecylammonium | — |
| P21/c | else | (C₁₃H₂₇NH₃)₂PbI₄ | 1 | Tridecylammonium | — |
| P21/c | RP | (C₁₃H₂₇NH₃)₂PbI₄ | 1 | Tridecylammonium | — |
| P212121 | else | (C₁₃H₂₇NH₃)₂PbI₄ | 1 | Tridecylammonium | — |
| P21/c | else | (C₁₅H₃₁NH₃)₂PbI₄ | 1 | Pentadecylammonium | — |
| P212121 | else | (C₁₅H₃₁NH₃)₂PbI₄ | 1 | Pentadecylammonium | — |
| C2/c | else | (C₈H₁₁FN)₂PbBr₄ | 1 | 4-fluorophenethylammonium | — |
| P21/c | else | (MACH)₂PbI₄ | 1 | Cyclohexanemethylammonium | — |
| Pbca | RP | (BA)₂PbBr₄ | 1 | Butylammonium | — |
| Cmce | RP | (BA)₂PbBr₄ | 1 | Butylammonium | — |
| Cmce | RP | (MACH)₂PbI₄ | 1 | Cyclohexanemethylammonium | — |
| Pmc21 | else | [(CH₃)₂CH(CH₂)₂NH₃]₂(CH₃NH₃)₂Pb₃Cl₁₀ | 3 | Butylammonium | Methyl- |
| | | | | | ammonium |
| 14/mmm | RP | [(CH₃)₂CH(CH₂)₂NH₃]₂(CH₃NH₃)₂Pb₃Cl₁₀ | 3 | Butylammonium | Methyl- |
| | | | | | ammonium |
| Cmc21 | else | (IA)₂(EA)₂Pb₃Br₁₀ | 3 | Isoamylammonium, | — |
| | | | | Ethylammonium | |
| P21/c | else | (PREA)₂PbI₄ | 1 | Ethylammonium pyrene | — |
| Pnma | else | (HCya)₂PbI₄ | 1 | Tioethylammonium | — |
| Cc | else | (FPEA)₂(MA)Pb₂I₇ | 2 | 4-fluorophenethylammonium | Methyl- |
| | | | | | ammonium |
| P212121 | else | (MPA)₂PbI₄ | 1 | β-methylphenethylammonium | — |
| Pbca | else | [C₇N₂H₁₈]PbBr₄ | 1 | Propylpiperazinium | — |
| C2/c | else | [₁,₃-C₆H₁₀N₂]PbBr₄ | 1 | 1,3-phenylenediammonium | — |
| P-1 | else | [₁,₄-C₆H₁₀N₂]PbBr₄ | 1 | 1,4-phenylenediammonium | — |
| P21/c | DJ | [₁,₄-C₈H₁₄N₂]PbBr₄ | 1 | 1,4-xylylenediammonium | — |
| P-1 | else | [C₆H₄CH₂CH₂NH₃]₂GeBr₄ | 1 | Phenylethylammonium | — |
| Pna21 | else | [BrC₆H₄CH₂CH₂NH₃]₂GeBr₄ | 1 | 2-bromophenylethylammonium | — |
| P21/c | else | [FC₆H₄CH₂CH₂NH₃]₂GeBr₄ | 1 | 2-fluorophenylethylammonium | — |
| (P21/n) | | | | | |
| P-1 | else | [C₆H₄CH₂NH₃]₂GeBr₄ | 1 | Benzylammonium | — |

In one or more embodiments, the 2D perovskite layer may include a 2D perovskite formed from a single-crystalline powder. Such powder may include crystals having a single n-value and a size range from micrometers to millimeters. Herein the single-crystalline powder is also referred to as a parent crystal. In one or more embodiments a parent crystal having a desired n-value is crystallized from a set of precursor materials. Suitable precursor materials include lead iodide (PbI₂), butylammonium iodide (BAI), methylammonium iodide (MAI), butylamine (BA), methylamine (MA), and combinations thereof. In one or more embodiments, the parent crystal has a high purity phase of a single n-value, ranging from 90 to 95%, as measured by X-ray diffraction.

In one or more embodiments, the 2D single-crystalline powder is used to prepare a 2D perovskite film. In such embodiments, the phase-pure parent crystal may then be dissolved in a suitable solvent at an elevated temperature. In one or more embodiments, the elevated temperature ranges from 60 to 100° C. and the suitable solvent is a polar aprotic solvent. In particular embodiments, the elevated temperature is 70° C. and the suitable solvent is dimethylformamide (DMF). The solution including the 2D single-crystalline powder may be processed via techniques such as spin casting, doctor blading, drop casting, and drop-die coating, and then annealed to provide a 2D perovskite film.

In one or more embodiments, the phase-pure 2D parent crystal is used to prepare a heterostructure. In such embodiments, the single-crystalline is dissolved in a processing solvent to provide a 2D perovskite seed solution. The dielectric constant (ε) of a solvent is a strong selection criterion for the choice of processing solvents for ionic solids. Additionally, recent reports have shown that the Lewis-acid base interactions play a major role in screening the processing solvents for halide perovskites. Although these are two distinct solvent properties, the coordination ability of a solvent and the dielectric constant are related. The Lewis basicity of the processing solvent, which is defined by Gutmann donor number (DN) describes the strength of the solvent to coordinate with a divalent metal (e.g., Pb²⁺ or Sn²⁺) by competing with the I-ions to prevent the formation of iodoplumbates (PbIₙ²⁻ⁿ, where n is 2 to 7) in the precursor solution of perovskites comprised of methylammonium iodide (MAI), formamidinium iodide (FAI), and lead iodide (PbI₂). In the case of crystalline perovskite compounds or powders (3D or 2D), the strength of the solvent coordination will result in a breakdown of the structures with the formation of soluble complexes in the solution.

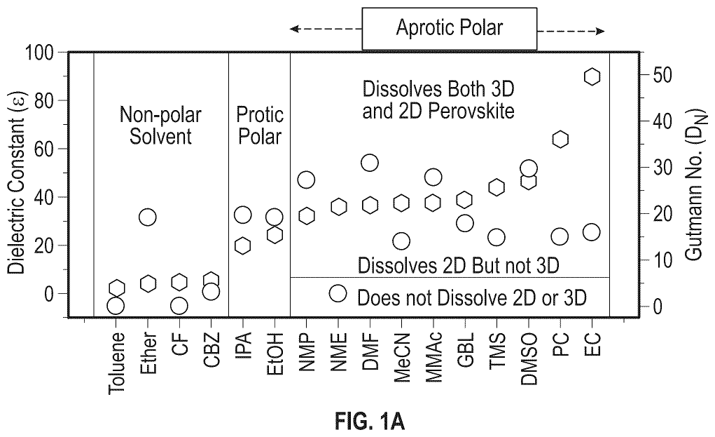

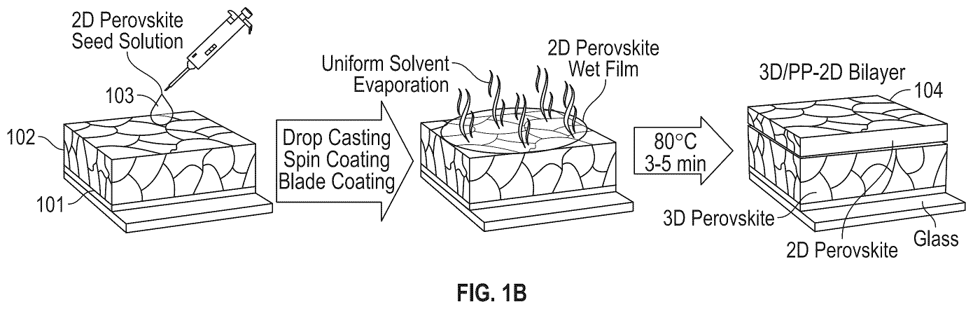

FIG. 1A summarizes the & and DN of different processing solvents, categorized according to the ability to form stable 2D perovskite dispersions while leaving the 3D perovskite intact. Non-polar solvents like ether, chloroform (CHF), and chlorobenzene (CBZ), do not dissolve both 3D and 2D perovskites. Hydrogen-bonded polar protic solvents such as ethanol, isopropanol, and water show a sluggish dissolution of the perovskites because of the differences in solubility of the organic cation, and the metal halide. Therefore, a stable perovskite solution may not be readily formed with these solvents.

In general, and consistent with previous reports, most polar aprotic solvents with ε>30 such as N, N-dimethylformamide (DMF), and dimethyl sulfoxide (DMSO), form stable 2D and 3D perovskite solutions, with some exceptions in the solubility, which appears to reasonable considering the DN of the solvent. Polar aprotic solvents acetonitrile (ACN), tetramethyl sulfone (TMS), propylene carbonate (PC), and ethylene carbonate (EC), having ε>30, do not dissolve 3D perovskite compounds, possibly owing to the weak Lewis acid-base interaction consistent with a value of DN less than 18 kcal/mol. However, these solvents form a stable 2D perovskite solution containing seeds of the 2D phase. A possible explanation is that the solvent partially disrupts the 2D lattice by extracting the interlayer organic molecules.

Accordingly, suitable processing solvents may have a dielectric constant ε>30 and a Guttman number 5<DN<18, as such properties provide for effective dissolution of the 2D perovskite powders without dissolving the 3D perovskites or other substrates that the 2D perovskite may be layered onto. In one or more embodiments, 2D seed solutions include ACN, TMS, PC, EC, or combinations thereof, as the processing solvent.

In one or more embodiments, processing solvents also have a low boiling point to enable uniform growth of the 2D perovskite layer and fast evaporation to avoid any diffusion or degradation of the underlying 3D perovskite layer. For example, suitable processing solvents may have a boiling point of equal to or less than 100° C. In particular embodiments, the processing solvent may be ACN.

In one or more embodiments, a method for fabricating mesoscopic 3D/2D heterostructures includes growing seed crystals from precursor materials. The 2D perovskite seed solution was prepared by dissolution of the seed crystals in an appropriate solvent. The 2D perovskite seed solution was used to prepare a 2D heterostructure via spin casting and annealing.

FIG. 1B illustrates a method for fabricating mesoscopic 3D/2D heterostructures according to one or more embodiments. As shown in FIG. 1B, the 2D perovskite seed solution 103 may be dispersed in ACN, and then dynamically spin casted on top of the control 3D perovskite layer 102 to form a 3D/2D bilayer comprising a 3D perovskite layer 102 and a 2D perovskite layer 104. The 3D perovskite layer may be disposed on a substrate layer 101. The bilayer may then be annealed at an elevated temperature for an amount of time. For example, the bilayer may be annealed at an elevated temperature ranging from 60° C. to 100° C. for an amount of time ranging from 1 to 10 minutes. In particular embodiments, the bilayer may be annealed at 80° C. for 5 minutes to provide a perovskite heterostructure in accordance with the present disclosure. This process may be compatible with other large-scale thin film processing techniques, such as doctor blading, drop casting, and slot-die coating. The disclosed method may provide control over the thickness and phase purity of the 2D perovskite layer in a perovskite heterostructure of one or more embodiments. For example, perovskite heterostructures prepared according to the previously described method may include a 2D perovskite layer having a phase purity of a single n-value of at least 90%. Further, the thickness of the 2D perovskite layer in a perovskite heterostructure of one or more embodiments may range from 1 nm to 1 μm.

In one or more embodiments, perovskite heterostructures may have an interface transition between the 3D perovskite layer and the 2D perovskite layer ranging from 15 to 25 nm.

In one or more embodiments, perovskite heterostructures may exhibit properties desirable for use in solar cells. In one or more embodiments, a solar cell device includes a substrate, an electron transport layer, a 2D perovskite film, a hole transport layer, and an indium doped tin oxide layer. The film may be a Ruddlesden-Popper film. The solar cell device may be a Dion-Jacobson device using a 2D perovskite film.

For example, a perovskite solar cell including a disclosed solvent-processed perovskite heterostructure film may have an efficiency of 24.5% giving a high open-circuit voltage (V_{OC}) of 1.2 V in a regular n-i-p device, Glass/ITO/SnO₂/3D-2D perovskite/Spiro-MeOTAD/Au using an overlying 2D, BA₂MA₂Pb₃I₁₀ perovskite having a thickness of 50 nm. In particular embodiments, the presence of the 2D heterostructure layer increases the overall efficiency by improving the charge transport characteristics due to the presence of an appropriate band alignment, and energy transfer due to the photogeneration ability of the 2D perovskite layer. Additionally, in a perovskite solar cell including the above exemplary perovskite heterostructure, a high ISOS-L1 photostability may be observed, with T99>2000 hours, implying such 3D/2D heterostructure films surpass the 2D perovskite stability, while the standard 3D/2D classically passivated PSC retains only 90% of its initial PCE after 1000 hours. The T₉₉ relates to the percent efficiency of the solar cell retained after certain hours of durability testing. Herein, T99>2000 hour describes that under constant illumination using simulated solar light, the photovoltaic device retained more than 99% of its original efficiency after 2000 hours.

The perovskite heterostructure disclosed herein may also be used for applications in bifacial, tandem solar cells, light emitting diodes, and photocatalysis.

Embodiments of the present disclosure may provide at least one of the following advantages. Existing technologies for making heterostructures of halide perovskites are underdeveloped due to the strict temperature and processing requirements and solvent incompatibilities. Existing techniques use organic cations for direct in-situ synthesis of a mixed layered perovskite on top of the 3D layer. In contrast, the present disclosure utilizes high purity 2D perovskite powders to create heterostructures, by selecting an optimized solvent that can effectively dissolve the 2D perovskite and not the 3D layer underneath. The present technique enables the growth of different phases of 2D perovskite layer with varying layered thicknesses (n=1-4), thus controlling the band alignment from type I to type II heterojunction for effective charge transport characteristics. The 2D perovskite layer shows high crystallinity comparable to films or crystals directly grown on the glass/quartz substrates. Disclosed methods exhibit control over the thickness of the underlying 3D and the capping 2D layer by maintaining high interfacial quality. The 2D perovskite layer may be deposited onto a variety of different 3D perovskite materials e.g., methylammonium lead iodide and formamidinium lead iodide. The present technique may be compatible with other large-scale thin film processing techniques, such as doctor blading, drop casting, and slot-die coating showing the scalability of the approach.

Herein, “includes”, and similarly for its variants such as “including”, is an open term encompassing includes, but is not limited to.

### EXAMPLES

### Example 1: Synthesis of a Ruddlesden Popper 2D Perovskite (n=3)

Lead oxide, methylamine hydrochloride (MACI), and butylamine (BA) were dissolved in an appropriate ratio in hydroiodic acid/hypophosphorous acid aqueous solution at 190° C. until boiling. The solution was left to cool and crystals of 2D Perovskite of BA₂MA₂Pb₃I₁₀ were obtained.

### Example 2: Synthesis of a Ruddlesden Popper 2D Perovskite (n=4)

Lead oxide, methylamine hydrochloride, and butylamine were dissolved in an appropriate ratio in hydroiodic acid/hypophosphorous acid aqueous solution at 190° C. until boiling. The solution was left to cool and crystals of 2D Perovskite of BA₂MA₃Pb₄I₁₃ were obtained.

### Example 3: Synthesis of a Dion Jacobson 2D Perovskite (n=4)

Lead oxide, methylammonium iodide, and 4-aminomethyl piperidine (4AMP) were dissolved in an hydroiodic acid/hypophosphorous acid aqueous solution at 240° C. until boiling. The solution was left to cool and crystals of 2D Perovskite (4AMP)-MA₂Pb₃I₁₀ were obtained.

### Example 4: Synthesis of a Perovskite Heterostructure Film

Solutions were prepared by dissolution of the 2D Perovskite of any of Examples 1-3 in an appropriate solvent or solvent solution at 70° C. for 6 hours. Solutions of each 2D Perovskite were prepared at 0.4 M in each of DMF, DMSO, DMF:DMSO (1:1), DMF:DMSO (1:1) with 1 uL of HI, and DMF-5 wt % MACI. Thin films were prepared by dropping 100 μL of prepared 2D Perovskite solution onto a substrate rotating at 4000 rpm, and rotating for 30 sec, followed by heating at 100° C.

### Example 5: Synthesis and Testing of BA₂MA₂PB₃I₁₀ 2D Perovskite Films

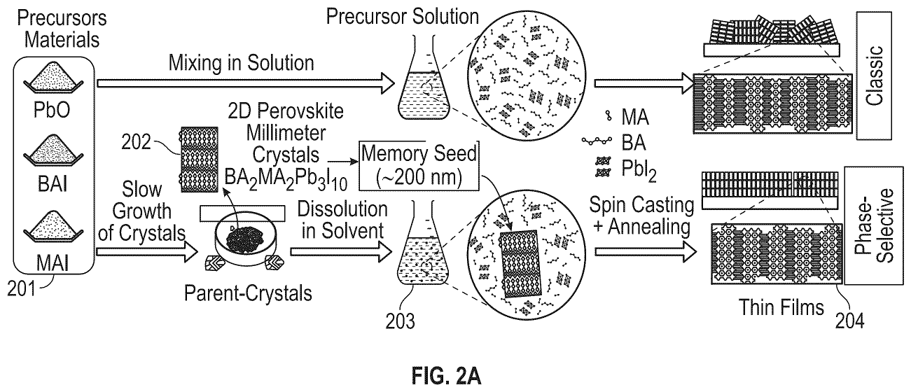

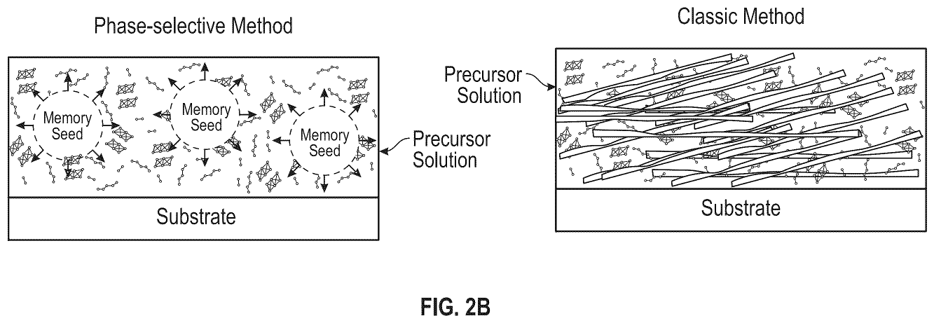

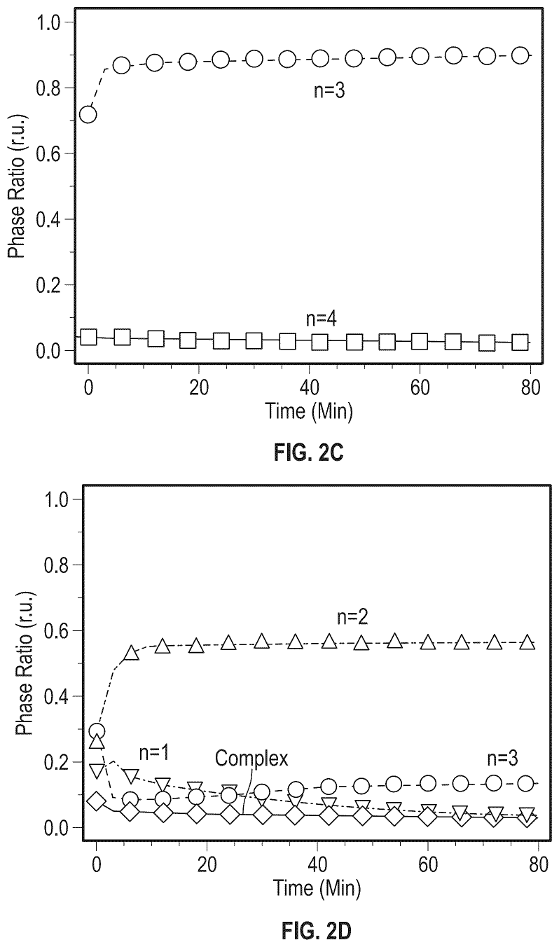

FIG. 2A illustrates a method used to fabricate mesoscopic 2D heterostructures for testing following the procedures of Examples 1 and 4. FIG. 2A further illustrates a comparative conventional (also herein termed “classic”) method for preparing films. In the present method, as shown in FIG. 2A, seed crystals were grown from precursor materials PbO, BAI, and MAI. The 2D perovskite seed solution was prepared by dissolution of the seed crystals of the BA₂MA₂Pb₃I₁₀ in an appropriate solvent. The 2D perovskite seed solution was used to prepare a 2D heterostructure via spin casting and annealing. Optical absorbance measurements of the 2D Perovskite seed solution showed an absorbance edge of 2.1 eV for n=2, 2.0 eV for n=3, and 1.85 eV for n=4 and exhibited phase purities of 90% or even 95%. The comparative classic method of preparing a 2D perovskite thin film included dissolving the precursor materials (e.g. PbI2, BAI, and MAI) for 12 hours in appropriate amount for the desired n value, and spin casting on a substrate and annealing at 100° C.

FIG. 2B illustrates a schematic of 2D perovskite layer on a substrate formed by the controlled ordered 2D perovskite seed growth layer on a substrate from the present method and a disordered layer formation formed by the comparative conventional method. The surface morphology of the 2D Perovskite films of BA₂MA₂Pb₃I₁₀ was characterized by scanning electron microscopy and atomic force microscopy. The results demonstrated that the present method produced micrometer sized order grains, whereas the comparative conventional method produced a disordered wirelike morphology.

The evolution of phase pure films was monitored over time by X-ray diffraction. The phase ratio may be obtained via integration of each phase relative to the total integrated diffraction as shown in FIGS. 2C and 2D. FIG. 2C shows evidence of the controlled growth, in comparison to the disordered layer formation from conventional methods shown evidenced in FIG. 2D. The integration of the diffraction pattern was measured over time up to 80 minutes at room temperature to slow kinetics of nucleation and film formation.

Grazing Incidence Wide Angle X-ray Scattering (GIWAXS) measurements demonstrated a phase purity of about 90% in BA₂MA₂Pb₃I₁₀ films. Comparative films prepared via conventional methods showed an estimated equal distribution of the desired phase and a phase impurity. Films according to one or more embodiments exhibited peaks corresponding to the 010, 101, 100, and/or 001 crystal planes.

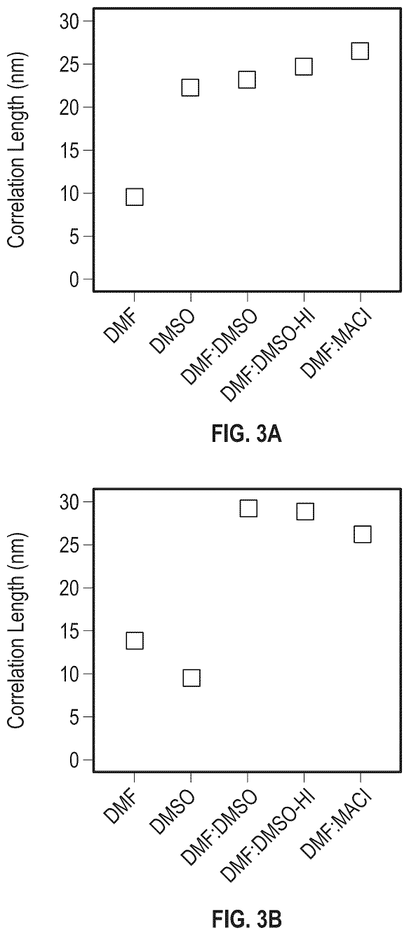

The average grain size, or correlation length, demonstrated in FIGS. 3A and 3B was obtained by diffraction techniques. Dynamic light scattering measurements of the particle size in 2D perovskite seed solutions were obtained which confirmed the grain size. Particle size distributions for the phase selective method exhibited bimodal distributions of about 1 nm or less and of about 100-400 nm particle sizes, or about 200 nm. The classic method of film preparation yielded monomodal particle size distributions of about 1 nm or less.

### Example 6: Production of an NiOₓ Perovskite Solar Cell

An indium doped tin oxide substrate was washed by ultrasonication for 15 min in each of water, acetone, acetone/ethanol (50:50) and isopropyl alcohol. The substrate was then dried under argon and UV treated for 30 minutes. A NiOₓ layer was deposited, by spin coating a solution prepared from Nickel (II) acetate tetrahydrate in ethanol with monoethylamine, at 5000 rpm for 30 sec. Under argon, a layer of the 2D perovskite was deposited by spin coating the solution from Example 4 onto the substrate rotating at 4000 rpm, and rotating for 30 sec, followed by heating at 100° C. Then a solution of PCBM was deposited by spin coating at 1000 rpm for 45 sec. A layer of aluminum was deposited by evaporation using a shadow mask to yield eight cells.

### Example 7: Production of a PEDOT:PSS Perovskite Solar Cell

An indium doped tin oxide substrate was washed by ultrasonication for 15 min in each of water, acetone, acetone/ethanol (50:50) and isopropyl alcohol. The substrate was then dried under argon and UV treated for 30 minutes. A PEDOT:PSS layer was deposited by spin coating at 5000 rpm for 30 sec. Under argon, a layer of the 2D perovskite was deposited by spin coating the solution from Example 4 onto the substrate rotating at 4000 rpm, and rotating for 30 sec, followed by heating at 100° C. Then a solution of PCBM was deposited by spin coating at 1000 rpm for 45 sec. A layer of aluminum was deposited by evaporation using a shadow mask to yield eight cells.

### Example 8: Production and Testing of Perovskite Solar Cells

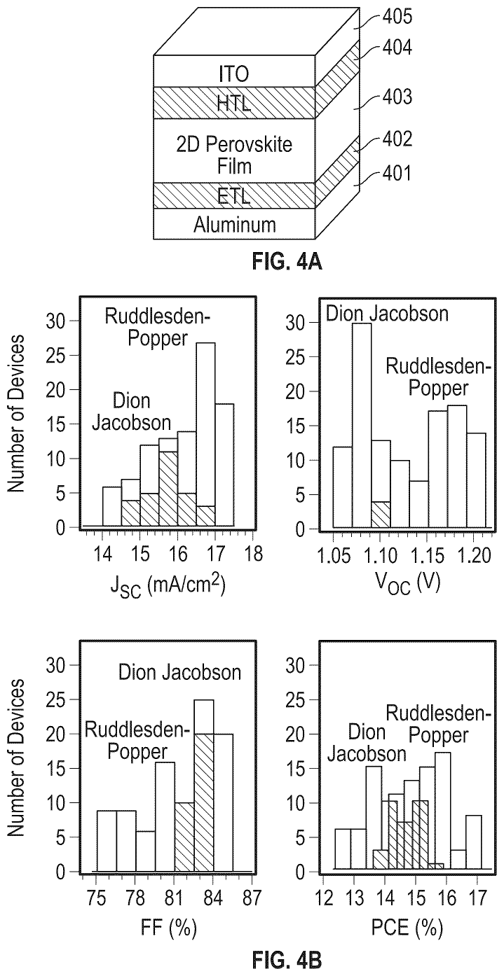

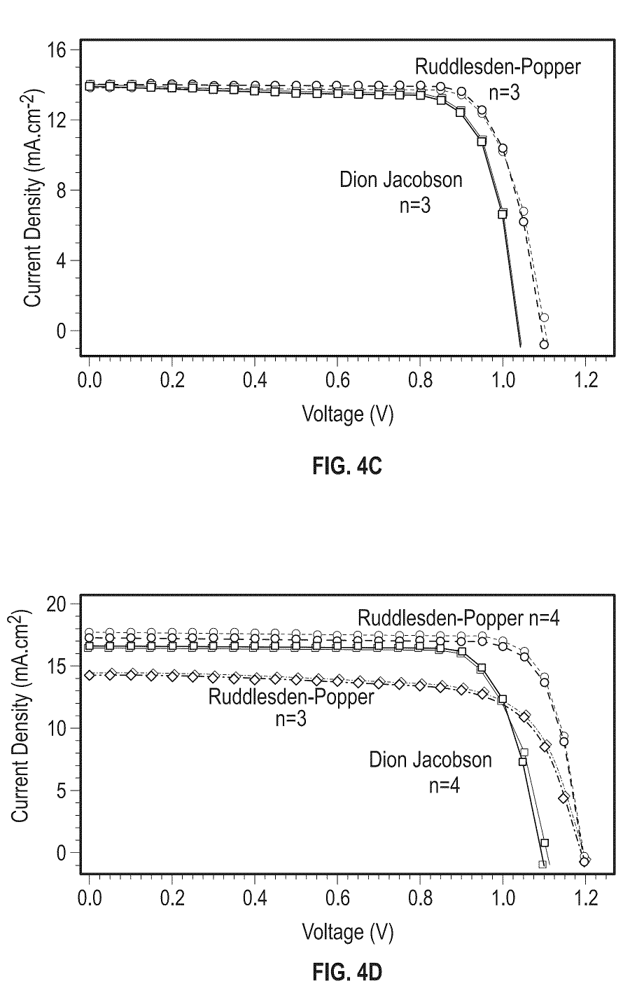

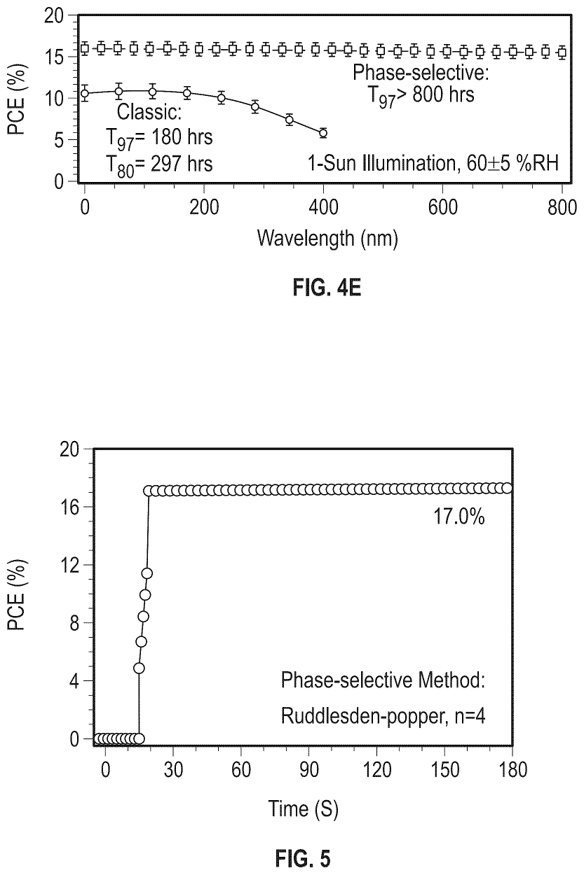

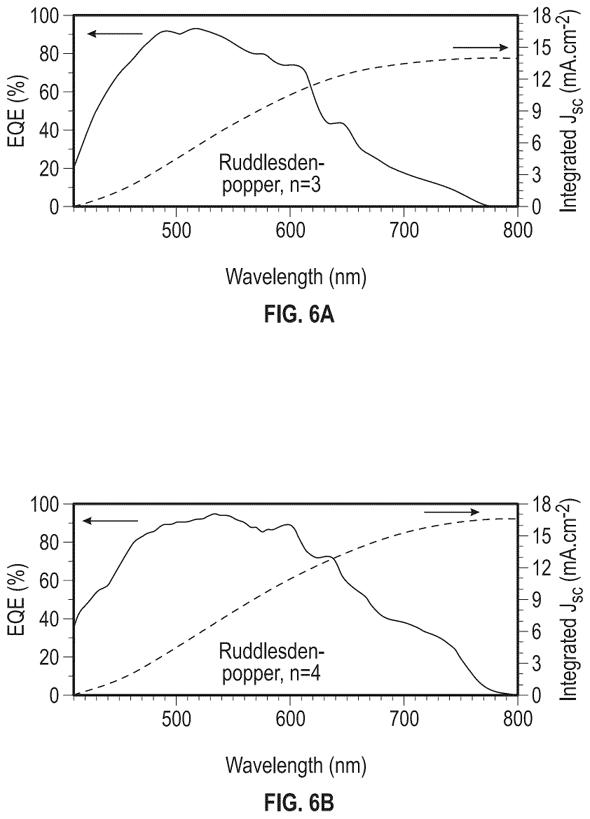

FIG. 4A illustrates a solar cell device, prepared for testing using the procedure of Example 6, and including a substrate 401 of aluminum, an electron transport layer 402 of PCBM, a 2D perovskite film 403 of BA₂MA₂Pb₃I₁₀, a hole transport layer 404 of NiO, and an indium doped tin oxide layer 405 for a Ruddlesden-Popper film containing device. A Dion-Jacobson device using a 2D perovskite film 403 of 4AMP-MA₃Pb₄I₁₃ was also produced. Current-voltage characteristics of solar cell devices were measured using a Newport ABB solar simulator (FIG. 4B-E). In FIG. 4B the devices use n=3 thin films of Ruddlesden-Popper (BA) and Dion-Jacobson (3AMP) prepared with the phase-selective method and a PEDOT:PSS HTL layer. The solar cell devices described in 4A had advantageously high current density, J_{SC}, V_{OC}, fill factor, and peak current efficiency as demonstrated in FIGS. 4C-E. The stability of an average of four devices is demonstrated in FIG. 4E for devices having an average efficiency (16.0±0.98%) for the phase selective method, for a Ruddlesden-Popper (BA) with n=4 solar cells under constant 1 sun illumination and 60±5% RH compared with the stability measured in a comparative thin-film solar cell with average efficiency (10.58±1.4%) fabricated with the classic method. FIG. 5 shows stabilized efficiency of 17.0% measured at a maximum power point of 0.99 for a Ruddlesden-popper, n=4 champion device having the structure described above regarding FIG. 4A and using BA₂MA₃Pb₄I₁₃ 2D perovskite layer and NiO as the HTL layer. The champion device exhibited J_{SC}=17.56 mA cm⁻², V_{OC}=1.20 V, fill factor 81.1%, and power conversion efficiency 17.1%. External quantum efficiencies of solar cell devices were measured using a 2 kHz quartz-tungsten-halogen source (FIGS. 6A-B). External quantum efficiencies of solar cell devices is in agreement with the J-V characteristics of the Ruddlesden-Popper n=3 BA₂MA₂Pb₃I₁₀ and n=4 BA₂MA₃Pb₄I₁₃ devices.

Photovoltaic parameters of solar cell devices prepared via the present phase-selective method and via the comparative conventional method are given in Table 2.

TABLE 2

| | Type of 2D | Scan | J_{sc}(mA · | | FF | PCE |
|---|---|---|---|---|---|---|
| Method | Perovskite | Direction | cm-2) | V_{oc}(V) | (%) | (%) |
| Phase- | BA2MA2Pb3I10 | Forward | 14.20 | 1.21 | 81.4 | 14.0 |
| selective | | Reverse | 14.28 | 1.22 | 82.0 | 14.3 |
| | BA2MA3Pb4I13 | Forward | 17.29 | 1.20 | 81.0 | 16.8 |
| | | Reverse | 17.56 | 1.20 | 81.1 | 17.1 |
| Con- | BA2MA2Pb3I10 | Forward | 12.48 | 0.96 | 65.0 | 7.8 |
| ventional | | Reverse | 12.91 | 1.00 | 72.0 | 9.3 |
| Method | BA2MA3Pb4I13 | Forward | 16.88 | 1.00 | 65.0 | 11.0 |
| | | Reverse | 17.09 | 1.02 | 75.0 | 13.1 |

### Example 9: Synthesis of a Perovskite Heterostructure Film

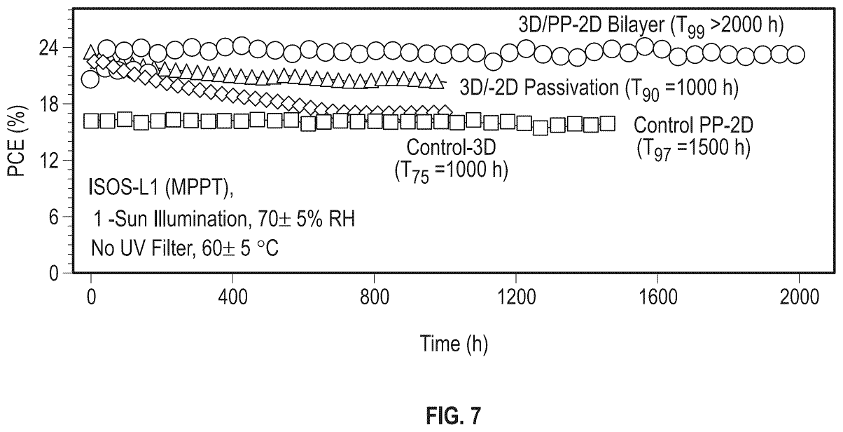

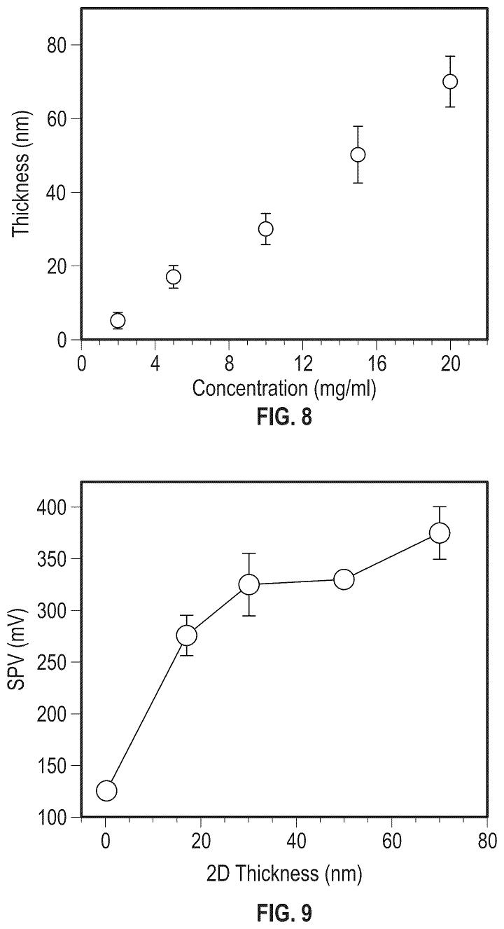

A solution was prepared by dissolution of the 2D Perovskite of any of Examples 1-3 in acetonitrile. Thin films were prepared by dropping 70 μL of prepared 2D Perovskite solution onto a 3D Perovskite substrate rotating at 4000 rpm, and rotating for 200 sec, followed by heating at 80° C. for 3-5 minutes. The stability of the 2D Perovskite films on a 3D Perovskite substrate, in an ITO/SnO2/3D/2D stack, is given in FIG. 7 for a device comprising a 2D perovskite film of BA₂MA₂Pb₃I₁₀ and a 3D perovskite layer of Cs₅(Ma0.10FA_{0.90})₉₅Pb(I0.90Br_{0.10})₃, as compared with a passivated 3D/2D perovskite heterostructure, and control samples of the 2D and 3D perovskite. The stabilities as measured at the maximum power point under ambient conditions and a continuous 1-sun illumination, 55 C for an epoxy encapsulated solar cell device. The initial PCE is 21$ for the control, 22.93 for the passivated 3D/2D perovskite heterostructure, 23.75% for the 3D/2D perovskite bilayer device, and 16.3% for the 2D perovskite. The thickness of the 2D Perovskite film on the 3D Perovskite substrate was modified by varying the concentration of the 2D Perovskite seed solution of BA₂MA₂Pb₃I₁₀ as shown in FIG. 8. As the 2D perovskite layer thickness is increased from 0 to 50 nm, the V_{OC} increases from 1.09 to 1.2 V, the fill factor increases from 0.80 to 0.84, the J_{SC} increases from 23.54 to 24.34 mA·cm⁻², which results in a PCE of 24.5% at a 2D perovskite thickness of 50 nm. As shown in FIG. 9, an increase in the 2D layer thickness corresponded to an increase in the measured surface photovoltage, as measured using scanning Kelvin probe microscopy for the device comprising the 2D perovskite film of BA₂MA₂Pb₃I₁₀.

Phase-purity of the 3D/2D Perovskite heterostructures was characterized by X-ray diffraction, optical absorbance, and photoluminescence. Optical absorbance measurements yielded exitonic peaks between 2.4 eV (n=1) and 1.9 eV (n=4). Photoluminescence measurements indicated a uniform emission from both the 2D perovskite layer and the 3D perovskite substrate.

Grazing incidence wide angle x-ray spectroscopy confirmed uniform layer growth of the 2D perovskite film on the 3D perovskite substrate layer. Diffraction patterns showed an oriented 2D perovskite diffraction pattern.

### Example 10: Production of a Perovskite Solar Cell

A glass/FTO substrate was washed by ultrasonication for 15 min in each of soap, water, acetone, and acetone/ethanol (50:50). The substrate was then dried under air and UV treated for 30 minutes. A SnO₂ film was deposited by spin coating from a SnO₂ colloid solution at 5000 rpm for 30 sec, followed by heating at 150° C. for 30 min. The substrate was UV-ozone treated for 15 minutes. A triple cation perovskite solution (TC), Cs₅(Ma0.10FA_{0.90})₉₅Pb(I0.90Br_{0.10})₃, was prepared by mixing: lead iodide, formamidinium iodide, lead bromide, and methylammonium bromide in DMF; with a solution of cesium iodide in DMSO. The TC solution was deposited onto the substrate by spin coating and annealing at 100° C. for 30-40 minutes. The 2D perovskite of any of examples 1-3 was dissolved in acetonitrile and spin coated onto the substrate. Then spiro-MeOTAD was spin coated onto the substrate from chlorobenzene solution with Li-TFSI/acetonitrile and tBP. An Au layer was deposited by evaporation.

### Example 11: Production of an Inverted Planar Perovskite Solar Cell

A glass/FTO substrate was washed by ultrasonication for 15 min in each of soap, water, acetone, and acetone/ethanol (50:50). The substrate was then dried under air and UV treated for 30 minutes. A polytriarylamine layer was spin coated from chlorobenzene and annealed at 150° C. for 10 min. A TC layer was deposited by spin coating a solution prepared from PbI₂, FAI, MABr, PbBr₂, and CsI in DMF:DMSO (4:1), i.e. Cs₅(Ma0.10FA_{0.90})₉₅Pb(I0.90Br_{0.10})₃, and annealing at 100° C. for 30-40 minutes. The 2D perovskite of any of examples 1-3 was dissolved in acetonitrile and spin coated onto the substrate. A layer of C60, BCP, and Copper was deposited by thermal evaporation.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112 (f) for any limitations of any of the claims herein, except for those in which the claim expressly uses the words ‘means for’ together with an associated function.

1. A method comprising:
providing a 2-dimensional (2D) perovskite seed solution comprising a 2D perovskite and a polar aprotic solvent;
layering the 2D perovskite seed solution onto a 3-dimensional (3D) perovskite layer to form a 3D/2D bilayer; and
annealing the 3D/2D bilayer such that the aprotic polar solvent evaporates to form a perovskite heterostructure film.

2. The method of claim 1, wherein the 2D perovskite has a general formula L′Aₙ₊₁BₙX₃ₙ₊₁, wherein L′ is a long chain organic cation, A is a small monovalent cation, B is a divalent metal, X is a monovalent anion, and n is a number of octahedra in a quantum well.

3. The method of claim 2, wherein n is less than or equal to 4.

4. The method of claim 1, where the 2D perovskite is a 2D halide perovskite selected from the group consisting of Ruddlesden-popper 2D perovskites, Dion-Jacobson 2D perovskites, Alternating Aation 2D perovskites, and combinations thereof.

5. (canceled)

6. The method of claim 1, further comprising:
prior to providing the 2D perovskite seed solution, crystallizing the single-crystal powder such that the single-crystal powder has a high phase purity of a desired n-value of at least 90%, as measured by one or more of X-ray diffraction and optical absorption.

7. The method of claim 1, wherein the polar aprotic solvent has a dielectric constant (ε) greater than or equal to 30.

8. (canceled)

9. (canceled)

10. The method of claim 1, wherein the 2D perovskite is soluble in the polar aprotic solvent and the 3D perovskite is insoluble in the polar aprotic solvent.

11. The method of claim 1, wherein the polar aprotic solvent is selected from the group consisting of acetonitrile, tetramethylene sulfone, polypropylene carbonate, ethylene carbonate, and combinations thereof.

12. The method of claim 11, wherein the polar aprotic solvent is acetonitrile.

13. The method of claim 1, wherein layering the 2D perovskite seed solution comprises: implementing a technique selected from the group consisting of spin casting, doctor blading, drop casting, drop-die coating, and combinations thereof.

14. The method of claim 1, wherein the perovskite heterostructure film comprises a 2D perovskite layer having a phase purity of a desired n-value ranging from 90 to 95%.

15. The method of claim 1, wherein the perovskite heterostructure film has a stability of T₉₉>2000 hours.

16. A perovskite solar cell comprising;
a solution-processed perovskite heterostructure comprising a 3-dimensional (3D) perovskite layer and a 2-dimensional (2D) perovskite layer, wherein the 2D perovskite layer has a phase purity ranging from 90 to 95%.

17. The perovskite solar cell of claim 16, wherein the solution-processed perovskite heterostructure comprises an interface transition between the 3D perovskite layer and the 2D perovskite layer ranging from 15 to 25 nm.

18. The perovskite solar cell of claim 16, wherein the 2D perovskite layer has a thickness ranging from 1 nm to 1 μm.

19. The perovskite solar cell of claim 16, wherein the 2D perovskite layer is highly crystalline.

20. The perovskite solar cell of claim 16, wherein the perovskite solar cell has a stability of T₉₉>1500 hours.

21. (canceled)

22. (canceled)

23. A method of preparing a phase-pure 2D perovskite comprising:
crystallizing a parent crystal from precursor materials selected from the group consisting of lead iodide (PbI₂), butylammonium iodide (BAI), methylammonium iodide (MAI), butylamine (BA), methylamine (MA), and combinations thereof, wherein the parent crystal has a single n-value;
dissolving the parent crystal into a solvent at an elevated temperature to form a parent crystal solution; and
processing the parent crystal solution such that a phase-pure 2D perovskite is formed.

24. The method of claim 23, wherein the processing comprises implementing a layering technique selected from the group consisting of spin casting, doctor blading, drop casting, drop-die coating, and combinations thereof, followed by annealing.

25. The method of claim 23, wherein the elevated temperature is 70.

26. (canceled)

27. (canceled)
